(19) United States
(12) Patent Application Publication
(10) Pub. No.: US 2014/0235069 A1
(43) Pub. Date: Aug. 21, 2014

(54) MULTI-PLENUM SHOWERHEAD WITH TEMPERATURE CONTROL

(71) Applicant: Novellus Systems, Inc., Fremont, CA (US)

(72) Inventors: Patrick G. Breiling, Tualatin, OR (US); Bhadri N. Varadarajan, Beaverton, OR (US); Jennifer L. Petraglia, Tualatin, OR (US); Bart J. van Schravendijk, Sunnyvale, CA (US); Karl F. Leeser, West Linn, OR (US); Mandyam Ammanjee Sriram, Beaverton, OR (US); Rachel E. Batzer, Beaverton, OR (US)

(21) Appl. No.: 13/934,620

(22) Filed: Jul. 3, 2013

Related U.S. Application Data
(60) Provisional application No. 61/765,432, filed on Feb. 15, 2013.
(60) Provisional application No. 61/770,251, filed on Feb. 27, 2013.

(51) Int. Cl. H01L 21/02; F28F 3/02; H01L 21/67

(52) U.S. Cl. CPC H01L 21/02271; H01L 21/02109; H01L 21/67017; F28F 3/02
USPC 438/778; 118/722; 239/548; 239/132; 165/185

(57) ABSTRACT

An apparatus for use with radical sources for supplying radicals during semiconductor processing operations is provided. The apparatus may include a stack of plates or components that form a faceplate assembly. The faceplate assembly may include a radical diffuser plate, a precursor delivery plate, and a thermal isolator interposed between the radical diffuser plate and the precursor delivery plate. The faceplate assembly may have a pattern of radical through-holes with centerlines substantially perpendicular to the radical diffuser plate. The thermal isolator may be configured to regulate heat flow between the radical diffuser plate and the precursor delivery plate.

### CROSS REFERENCE TO RELATED APPLICATIONS

This application claims benefit under 35 U.S.C. §119(e) to U.S. Provisional Application Nos. 61/765,432, filed Feb. 15, 2013, and 61/770,251, filed Feb. 27, 2013, both titled “MULTI-PLENUM SHOWERHEAD WITH TEMPERATURE CONTROL,” which are both hereby incorporated by reference herein in their entireties.

### BACKGROUND OF THE INVENTION

Semiconductor processing tools often use radical sources to distribute radicalized process gas across a semiconductor wafer during processing, e.g., during chemical vapor deposition (CVD) or atomic layer deposition (ALD) processing. Such radical sources may include a faceplate that faces the wafer during processing, and a number of gas distribution holes may be distributed across the faceplate to facilitate radicalized gas delivery to the wafer from within the radical source.

During some semiconductor manufacturing processes, e.g., plasma-enhanced chemical vapor deposition (PECVD), semiconductor fabrication process gases may be converted into a plasma to produce radicals used in various process steps. Such plasma-enhanced processes may provide advantages over, for example, thermal CVD since such processes may be performed with lower process temperatures and greater flexibility in process chemistry. Plasma conversion, however, may also be damaging to the wafer, e.g., by oxidizing the underlying silicon of the wafer or an ultra-low K dielectric used in the process. To reduce such damage potential, such plasmas may be located so as to be “remote” from the wafer; one such process is commonly referred to as remote plasma deposition (RPD). For example, some radical sources may have an internal volume within which the plasma may be generated. This internal volume may be separated from the wafer by the radical source faceplate (making the plasma “remote” from the wafer), somewhat shielding the wafer from possible damage arising from plasma conversion. The gas distribution holes in the faceplate may allow radicals produced by the remotely-generated plasma to flow out of the radical source and onto the wafer.

### SUMMARY OF THE INVENTION

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale unless specifically indicated as being scaled drawings.

In some implementations, an showerhead for semiconductor processing operations may be provided. The showerhead may include a precursor delivery plate with a first side and an opposing second side and a radical diffuser plate with a first side and an opposing second side. The second side of the radical diffuser plate may face the first side of the precursor delivery plate. The showerhead may also include a thermal isolator interposed between the precursor delivery plate and the radical diffuser plate. The showerhead may also include a pattern of radical through-holes. Each of the radical through-holes may pass through the precursor delivery plate, the radical diffuser plate, and the thermal isolator. Each of the radical through-holes may also have a hole center axis that is substantially normal to the precursor delivery plate, the radical diffuser plate, and the thermal isolator and may maintain a substantially uniform cross-sectional area perpendicular to the hole center axis of the radical through-hole through the precursor delivery plate, the radical diffuser plate, and the thermal isolator.

In some further implementations, the thermal isolator may be configured to control heat flow between the radical diffuser plate and the precursor delivery plate to be less than the heat flow between the radical diffuser plate and the precursor delivery plate would be were the radical diffuser plate and the precursor delivery plate to be in direct thermal contact and thickened such that the first side of the radical diffuser plate and the second side of the precursor delivery plate remain at the same distance.

In some further implementations of the showerhead, the precursor delivery plate may include a pattern of gas delivery holes and one or more internal gas distribution passages. Each of the gas delivery holes may have a hole center axis that is substantially normal to the precursor delivery plate, the radical diffuser plate, and the thermal isolator. Each of the gas delivery holes may also be fluidly connected to at least one of the one or more gas distribution passages and each of the gas delivery holes may exit the precursor delivery plate on the second side of the precursor delivery plate.

In some implementations of the showerhead, the radical through-holes may have a length-to-diameter ratio of between 7:1 and 10:1. In some other implementations of the showerhead, the radical through-holes have a length-to-diameter ratio of between 6:1 and 11:1. In some implementations of the showerhead, the radical through-holes may have a length of at least 0.25″.

In some implementations of the showerhead, the radical diffuser plate may include one or more first internal cooling passages extending across the radical diffuser plate. The one or more first internal cooling passages may be fluidly isolated from the radical through-holes within the radical diffuser plate.

In some such implementations of the showerhead, the first internal cooling passages may include an array of passages. Each passage may follow a path that is, on average, substantially parallel to a reference plane that is substantially perpendicular to the first side of the radical diffuser plate, and each passage may have a first end fluidly connected with an inlet and a second end fluidly connected with an outlet. In some other implementations of the showerhead, each passage may follow a path that is, on average, substantially parallel to a reference plane that is substantially perpendicular to the first side of the radical diffuser plate, and each passage that is located on a first side of the reference plane may have a first end fluidly connected with a first inlet and a second end fluidly connected with a first outlet, and each passage that is located on a second side of the reference plane opposite the first side of the reference plane may have a first end fluidly connected with a second inlet and a second end fluidly connected with a second outlet. In some such implementations, the first inlet, the second inlet, the first outlet, and the second outlet may each be connected with their respective passages via separate coolant plenums that are substantially arcuate in shape and that are radially arranged about a center axis of the radical diffuser plate.

In some implementations of the showerhead, the first internal cooling passages may include an array of first passages. Each of the first passages may follow a first path that is, on average, substantially parallel to a reference plane that is substantially perpendicular to the first side of the radical diffuser plate. The first internal cooling passages may include an array of second passages, and each of the second passages may follow a second path that is, on average, substantially parallel to the reference plane. The first passages and the second passages may be fluidly isolated from one another within the radical diffuser plate. Each first passage may have a first end that is fluidly connected with a first inlet and a second end opposite the first end of the first passage that is fluidly connected with a first outlet. Each second passage may have a first end that is fluidly connected with a second inlet and a second end opposite the first end of the second passage that is fluidly connected with a second outlet. The first inlet, the second inlet, the first outlet, and the second outlet may be configured such that cooling fluid flowed into the first inlet flows through the first passages and out of the first outlet in a first average direction and cooling fluid flowed into the second inlet flows through the second passages and out of the second outlet in a second average direction. The first average direction and the second average direction may be substantially opposing directions.

In some implementations of the showerhead, the showerhead may further include a circumferential plenum. The circumferential plenum may have an interior perimeter, be proximate to the first side of the radical diffuser plate, and be configured to flow gas in a substantially evenly-distributed manner across the interior perimeter and substantially towards a center axis of the radical diffuser plate.

In some implementations of the showerhead, the showerhead may further include a plasma dome. The plasma dome may have an interior surface that is substantially axially symmetric about the center axis of the radical diffuser plate, one or more radical gas inlets located on one end of the plasma dome near the center axis of the radical diffuser plate, and a mounting interface located on an opposing end of the plasma dome and configured to connect the plasma dome with the showerhead such that the interior surface of the plasma dome and the first side of the radical diffuser plate define a radical source volume and such that gas flow from the circumferential plenum flows into the radical source volume.

In some implementations of the showerhead, the circumferential plenum may be located in an adapter interposed between the plasma dome and the radical diffuser plate. In some other implementations of the showerhead, the circumferential plenum may be located in the plasma dome near the mounting interface.

In some implementations of the showerhead, the thermal isolator may be a plate with a thermal conductivity substantially lower than respective thermal conductivities of the precursor delivery plate and the radical diffuser plate. In some other implementations of the showerhead, the thermal isolator may have a gap between the radical diffuser plate and the precursor delivery plate. The gap may define a free volume between the radical diffuser plate and the precursor delivery plate. The thermal isolator may also include a number of tubular structures corresponding to the number of radical through-holes in the pattern of radical through-holes. Each tubular structure may correspond with a different one of the radical through-holes, have an internal diameter substantially equal to a nominal diameter of the corresponding radical through-hole, span the gap, and substantially isolate the radical through-hole from the free volume with respect to fluidic communication.

In some further implementations of the showerhead, at least one of the tubular structures may be a discrete tube segment. In some further implementations of the showerhead, the at least one of the tubular structures is made from a material selected from the group consisting of quartz or sapphire.

In some implementations of the showerhead, the thermal isolator may include at least two stacked layers, each layer including the radical through holes. In some further such implementations, the thermal isolator may further include a first interface between a first mating surface of one of the layers and a second mating surface of a neighboring layer, and at least one of the first mating surface and the second mating surface may have a surface roughness Ra value of about 8 to 16 microinches or higher. In some implementations, the layers may have an absolute flatness of about 0.002″ across each layer.

In some implementations of the showerhead, the radical through-holes may exit the second side of the precursor delivery plate via openings on a first plane and the gas delivery holes may exit the second side of the precursor delivery plate via openings on a second plane offset from the first plane by a first, non-zero distance in a direction away from the first side of the precursor delivery plate. In some implementations, the first, non-zero distance may be greater than 0.25″. In some implementations, the first, non-zero distance may be between 0.25″ and 3″. In some implementations, the first, non-zero distance may be between 3″ and 12″.

In some implementations of the showerhead, the radical through-holes may exit the second side of the precursor delivery plate via openings on a first plane and the gas delivery holes may exit the second side of the precursor delivery plate via openings on a second plane offset from the first plane in a direction away from the first side of the precursor delivery plate and far enough that radicalized gas flowed from the radical diffuser plate via the openings on the first plane exhibits substantially fully-developed flow before encountering the second plane.

In some implementations of the showerhead, the radical diffuser plate is at least partially coated with a material that inhibits radical recombination with the radical diffuser plate. In some such implementations, the material may be selected from the group consisting of aluminum nitride, quartz, and sapphire.

In some implementations, the showerhead may further include a process chamber. In such implementations, the radical diffuser plate, the thermal isolator, and the precursor delivery plate may be configured to deliver process gases to the process chamber.

In some such implementations, the showerhead may further include one or more additional process chambers, and the process chamber and the one or more additional process chambers may form a multi-chamber semiconductor processing tool.

In some other such implementations, the showerhead may further comprise a second radical diffuser plate, a second thermal isolator, and a second precursor delivery plate. The second radical diffuser plate, the second thermal isolator, and the second precursor delivery plate may be arranged in a manner similar to the radical diffuser plate, the thermal isolator, and the precursor delivery plate. The process chamber may also include at least a first processing station and a second processing station. The radical diffuser plate, the thermal isolator, and the precursor delivery plate may be configured to deliver process gas to the first processing station, and the second radical diffuser plate, the second thermal isolator, and the second precursor delivery plate may be configured to deliver process gas to the second processing station.

In some implementations, a method for using a showerhead for semiconductor processing operations is provided. The showerhead may include a precursor delivery plate with a first side and an opposing second side and a radical diffuser plate with a first side and an opposing second side. The second side of the radical diffuser plate may face the first side of the precursor delivery plate. The apparatus may also include a thermal isolator interposed between the precursor delivery plate and the radical diffuser plate. The apparatus may also include a pattern of radical through-holes. Each of the radical through-holes may pass through the precursor delivery plate, the radical diffuser plate, and the thermal isolator. Each of the radical through-holes may also have a hole center axis that is substantially normal to the precursor delivery plate, the radical diffuser plate, and the thermal isolator and may maintain a substantially uniform cross-sectional area perpendicular to the hole center axis of the radical through-hole through the precursor delivery plate, the radical diffuser plate, and the thermal isolator. The method may include maintaining the precursor delivery plate at a first temperature; maintaining the radical diffuser plate at a second temperature; providing a first process gas via the gas delivery holes while the precursor delivery plate is at the first temperature; and providing a second process gas via the radical through-holes while the radical diffuser plate is at the second temperature.

In some implementations, a reactor for semiconductor processing operations may be provided. The reactor may include a reaction chamber, a wafer support located within the reaction chamber, and a showerhead. The showerhead may include a precursor delivery plate with a first side and an opposing second side and a radical diffuser plate with a first side and an opposing second side. The second side of the radical diffuser plate may face the first side of the precursor delivery plate. The apparatus may also include a thermal isolator interposed between the precursor delivery plate and the radical diffuser plate. The apparatus may also include a pattern of radical through-holes. Each of the radical through-holes may pass through the precursor delivery plate, the radical diffuser plate, and the thermal isolator. Each of the radical through-holes may also have a hole center axis that is substantially normal to the precursor delivery plate, the radical diffuser plate, and the thermal isolator and may maintain a substantially uniform cross-sectional area perpendicular to the hole center axis of the radical through-hole through the precursor delivery plate, the radical diffuser plate, and the thermal isolator. The showerhead and the wafer support may be configured such that the wafer support is beneath the showerhead within the reaction chamber.

In some implementations, a thermal isolator may be provided. The thermal isolator may include a first side; a second side substantially parallel to, and offset from, the first side; and a plurality of tubular structures spanning between the first side and the second side, the tubular structures arranged in a distributed pattern across the first side and the second side. The tubular structures may substantially prevent fluid flow between volumes within the tubular structures and a volume substantially defined between the first side and the second side.

In some further such implementations, the thermal isolator may further include a perimeter wall spanning between the first side and the second side and encircling the plurality of tubular structures. The perimeter wall, the first side, the second side, and outermost surfaces of the tubular structures may define a hollow internal volume of the thermal isolator.

In yet some further implementations of the thermal isolator, the thermal isolator may further include one or more ports in fluid communication with the hollow internal volume of the thermal isolator.

These and other aspects of this disclosure are discussed in further detail below.

### BRIEF DESCRIPTION OF THE DRAWINGS

FIG. 1A depicts a high-level schematic of an example of a remote plasma source with a tri-partitioned faceplate assembly during a radicalized gas flow operation.

FIG. 1B depicts a high-level schematic of the remote plasma source of FIG. 1A during an operation in which radicalized gas flow through the faceplate is inhibited.

FIG. 2A depicts a high-level schematic of one example of a tri-partitioned faceplate assembly featuring a perforated plate that acts as a thermal isolator.

FIG. 2B depicts a high-level schematic of one example of a tri-partitioned faceplate assembly featuring a hollow plate that acts as a thermal isolator.

FIG. 2C depicts a high-level schematic of one example of a tri-partitioned faceplate assembly featuring an alternate hollow plate thermal isolator design.

FIG. 2D depicts a high-level schematic of one example of a tri-partitioned faceplate assembly featuring a thermal isolator featuring a plurality of discrete tubes.

FIG. 2E depicts a high-level schematic of one example of a tri-partitioned faceplate assembly featuring offset gas distribution hole and radical through-hole exits.

FIG. 3A depicts a schematic showing substantially straight cooling channel paths.

FIG. 3B depicts a schematic also showing substantially straight cooling channel paths.

FIG. 4A depicts an isometric view of one example of a tri-partitioned faceplate assembly.

FIG. 4B depicts an isometric view of the faceplate assembly of FIG. 4A with multiple portions cut away for viewing of interior features.

FIG. 4C depicts an isometric exploded view of the faceplate assembly of FIG. 4A with some components having portions cut away for viewing of interior features.

FIG. 5A depicts an isometric exploded view of one example of a radical diffuser plate with opposing flow cooling channels.

FIG. 5B depicts a first side of the midplate of the radical diffuser plate of FIG. 5A.

FIG. 5C depicts a second side of the midplate of the radical diffuser plate of FIG. 5A.

FIG. 6A depicts an isometric section view of one example of a precursor delivery plate.

FIG. 6B depicts a bottom view of the precursor delivery plate of FIG. 6A.

FIG. 6C depicts a side section view of the precursor delivery plate of FIG. 6A.

FIG. 6D depicts an exploded reverse isometric view of the precursor delivery plate of FIG. 6A.

FIG. 7A depicts an isometric exploded view of one example of a faceplate assembly.

FIG. 7B depicts an isometric view of the faceplate assembly of FIG. 7A with some portions cut away for viewing of interior features.

FIG. 8A depicts a dimetric section view of one example of a tri-partitioned faceplate assembly.

FIG. 8B depicts a detail view of a portion of the example sectioned tri-partitioned faceplate assembly of FIG. 8A.

FIG. 8C depicts a dimetric section exploded view of the example tri-partitioned faceplate assembly of FIG. 8A.

FIG. 8D depicts another dimetric exploded section view of the example tri-partitioned faceplate assembly of FIG. 8A with the upper portions of the radical diffuser plate and the precursor delivery plate removed to allow viewing of internal features.

FIGS. 8E through 8H depict conceptual schematics indicating the effect of surface roughness on actual contact area between two mating surfaces.

FIG. 9 shows a schematic view of a multi-station processing tool that may be used with the components described herein.

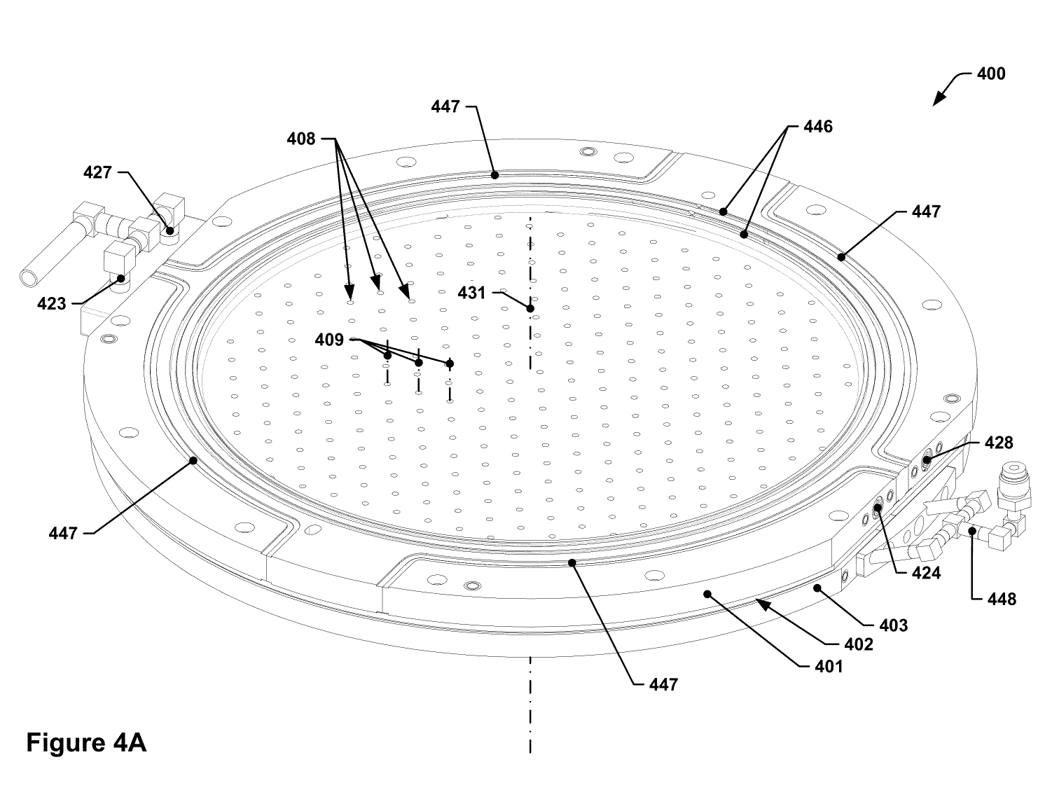

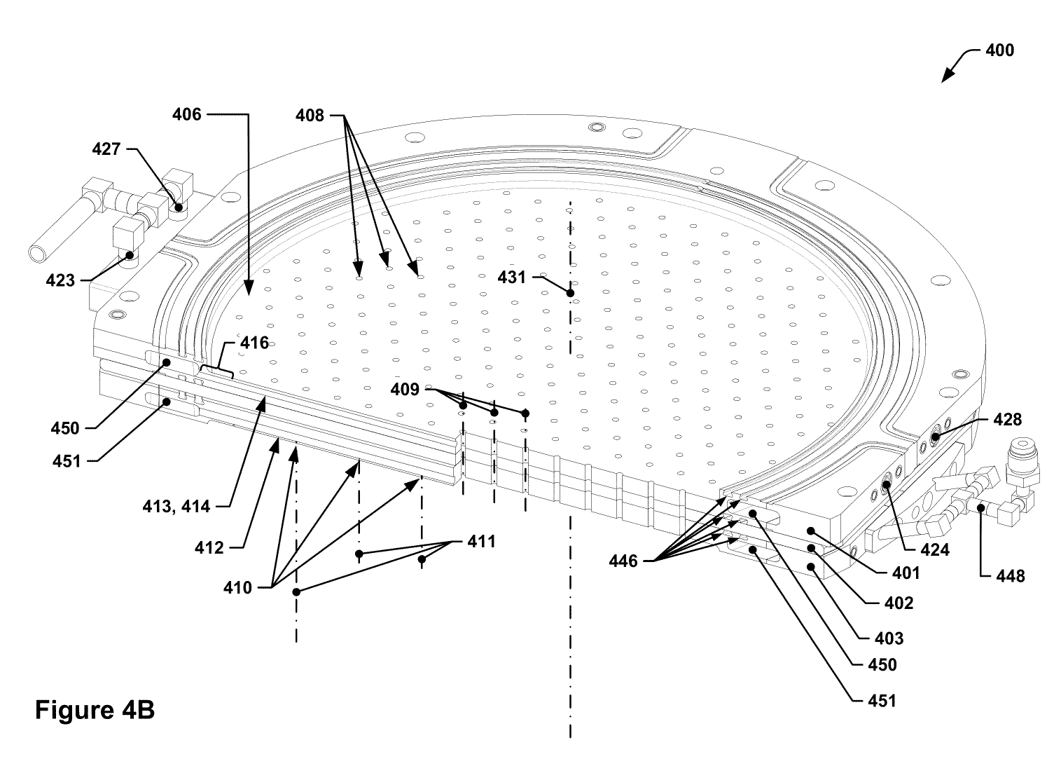

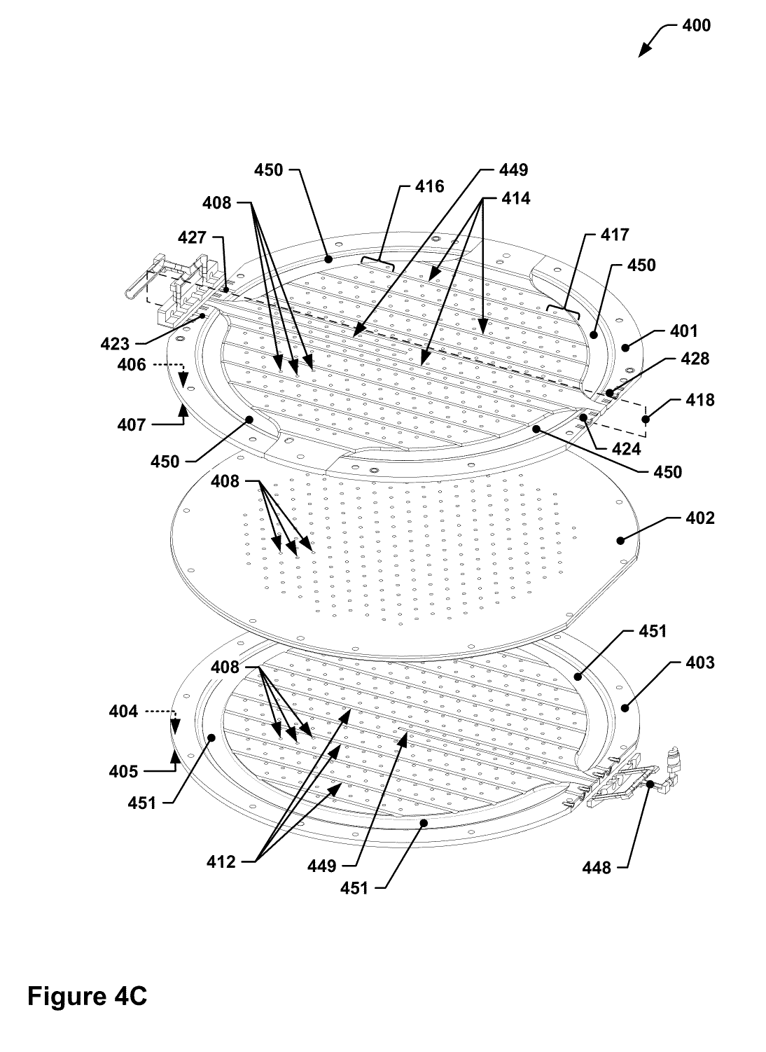

FIGS. 4A through 8D are drawn to scale within each Figure.

### DETAILED DESCRIPTION

Examples of various implementations are illustrated in the accompanying drawings and described further below. It will be understood that the discussion herein is not intended to limit the claims to the specific implementations described. On the contrary, it is intended to cover alternatives, modifications, and equivalents as may be included within the spirit and scope of the invention as defined by the appended claims. In the following description, numerous implementation-specific details are set forth in order to provide a thorough understanding of the present invention. The present invention may be practiced without some or all of these implementation-specific details. In other instances, well-known process operations have not been described in detail in order not to unnecessarily obscure the present invention.

Described herein are various implementations of a tri-partitioned faceplate assembly for a showerhead for use with remote plasma sources, as well as other features that may be used with remote plasma sources. It is to be understood that while the phrase “tri-partitioned” may be used to refer to faceplate assemblies with three major components, the phrase “tri-partitioned” may also be used to refer to faceplate assemblies with more or fewer major components that define three distinct zones, each zone providing functionality similar to that discussed below with respect to the major components of the faceplate assemblies discussed below.

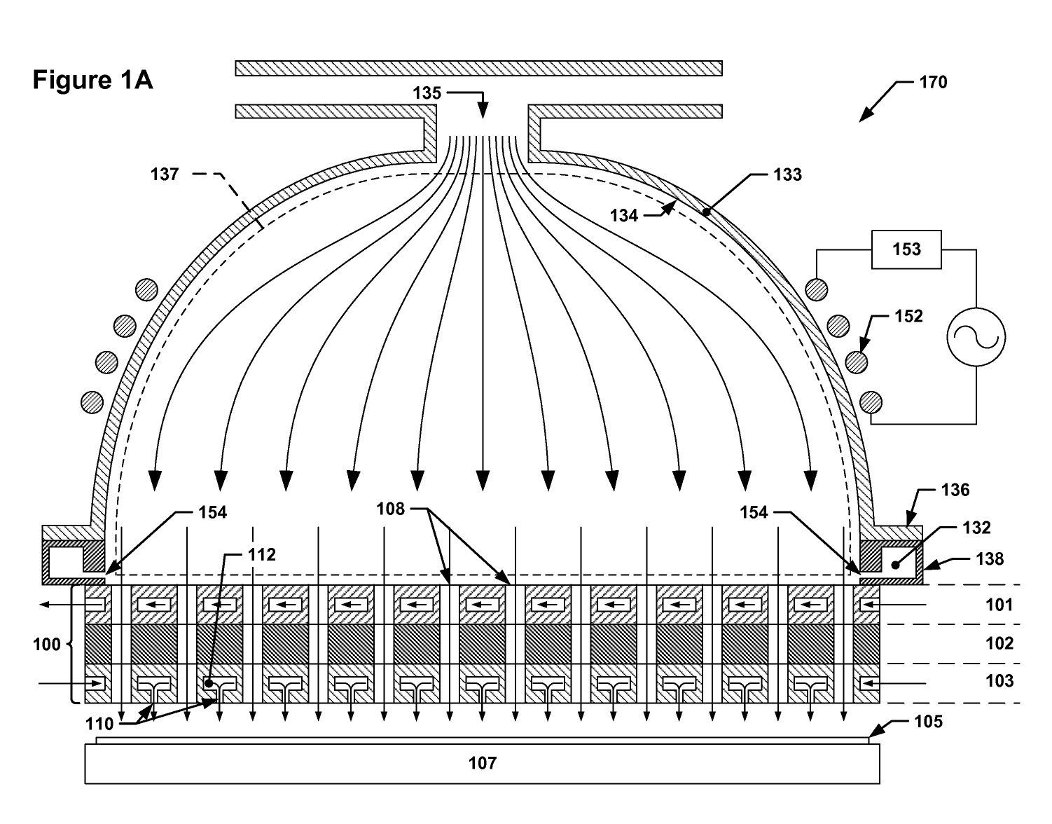

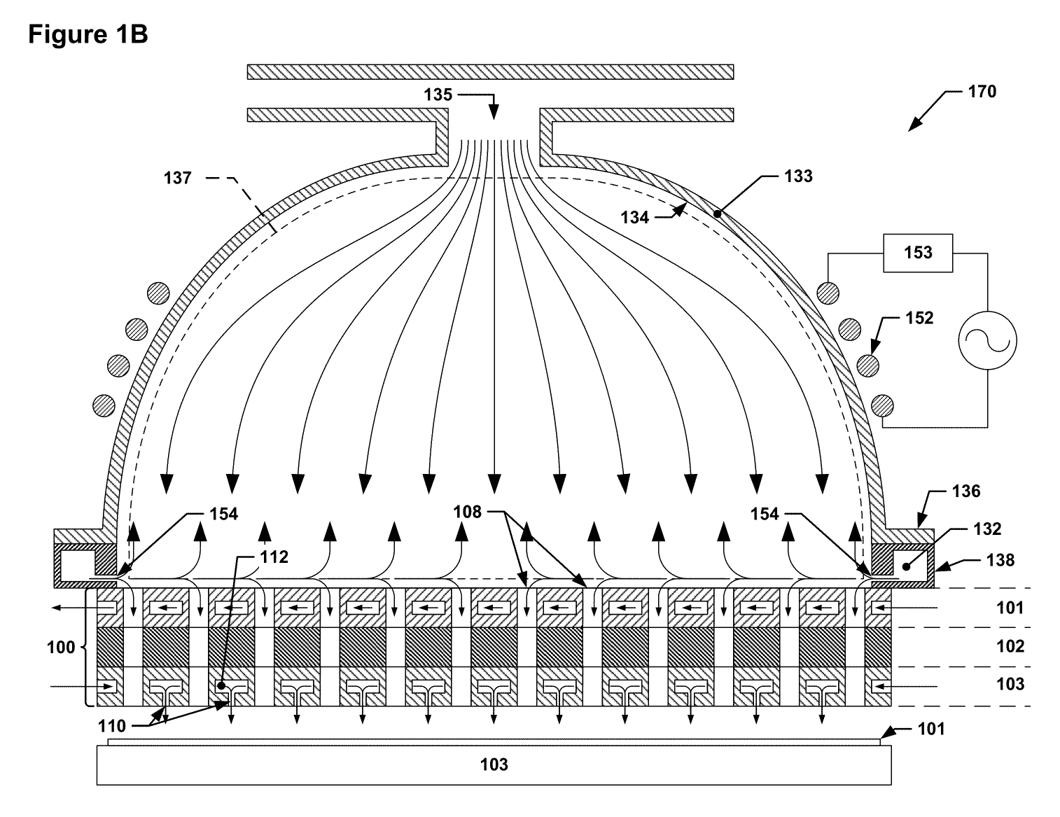

FIG. 1A depicts a high-level schematic of an example of a remote plasma source with a tri-partitioned faceplate assembly during a radicalized gas flow operation. A remote plasma source 170 is shown, including a faceplate assembly 100 including a radical diffuser plate 101, a precursor delivery plate 103, and a thermal isolator 102 interposed between the radical diffuser plate 101 and the precursor delivery plate 103. A plasma dome 133 may be connected with the faceplate assembly via a mounting interface 136, e.g., a mounting flange, shoulder, or other feature, to form a radical source volume 137, e.g., a volume bounded by the faceplate assembly and an interior surface 134 of the plasma dome 133. In some implementations, a plasma dome may not be used, but a more conventional cover, e.g., a flat back plate or other shape that forms a substantially cylindrical radical source volume 137, such as may be found on conventional showerheads used in semiconductor processing operations. A plenum adapter 138 may be interposed between the plasma dome 133 (or alternate structure, e.g., flat back plate or other structure, as detailed above) and the faceplate assembly 100. The plenum adapter 138 may include a circumferential plenum 154 configured to flow a process gas via one or more radial inlets 154 into the radical source volume 137. In FIG. 1A, there is no gas flow through the one or more radial inlets 154. The one or more radial inlets 154 may be discrete inlets arranged in a circular array, or may be one or more arc-shaped “air knife” inlets featuring thin, arced slots in the circumferential plenum 154.

It is to be understood that while FIGS. 1A and 1B depict a remote plasma source similar to those found in inductively coupled plasma (ICP) systems, the faceplate assembly 100, as well as other components such as the plenum adapter 138, may be used with a variety of technologies that may be used to deliver radicals to the volume above the radical diffuser plate 101. For example, the faceplate assembly 100 may be used with radical generation techniques that utilize ultraviolet light to produce radicals, capacitively-coupled plasma techniques, microwave plasma generators, and other types of radical-generation technology. The radicals may be generated within the radical source volume 137 directly, or may be supplied from an external source, such as an ASTRONi™ reactive gas generator, provided by MKS Instruments, that generates radicals outside of the radical source volume 137 and then delivers the radicalized gas into the radical source volume 137 via one or more delivery ports.

A first process gas may be flowed into the apparatus via one or more radical gas inlets 135. A plasma may be generated using the first process gas using radio-frequency coils 152, which may be connected to an RF source via a matching network 153. The radicalized first process gas may flow towards the radical diffuser plate 101 and through one or more radical through-holes 108 to reach a wafer reaction area located between the faceplate assembly 100 and a wafer 105 being processed using the remote plasma source 170 (or between the faceplate assembly 100 and a wafer support 107). At the same time, a precursor gas may be flowed into one or more precursor gas inlets and through internal gas distribution passages 112 to gas delivery holes 110. Thus, precursor gas and radicalized first process gas may be delivered to the wafer reaction area simultaneously.

FIG. 1B depicts a high-level schematic of the remote plasma source of FIG. 1A during an operation in which radicalized gas flow through the faceplate is inhibited. In FIG. 1B, a second process gas may be introduced to the radical source volume 137 via the one or more radial inlets 154. The one or more radial inlets 154 may be configured to direct the second process gas across the radical diffuser plate, forming a layer of second process gas between the first process gas and the radical diffuser plate 101. The flow of the second process gas may counteract, at least partially, the flow of the first process gas towards the radical diffuser plate 101, thus at least partially preventing flow of the radicalized first process gas through the radical through-holes 108 while the second process gas is flowed through the one or more radial inlets 154. For applications in which radical gas is desirably prevented from reaching the process reaction area during some operations, such second process gas flows may obviate the need to purge the radical source volume of the radical gas (which may also involve extinguishing the plasma) during those operations. The second process gas may, for example, be an inert carrier gas or may be the same as the first process gas. In some implementations, the second process gas may be a non-carrier gas different from the first process gas.

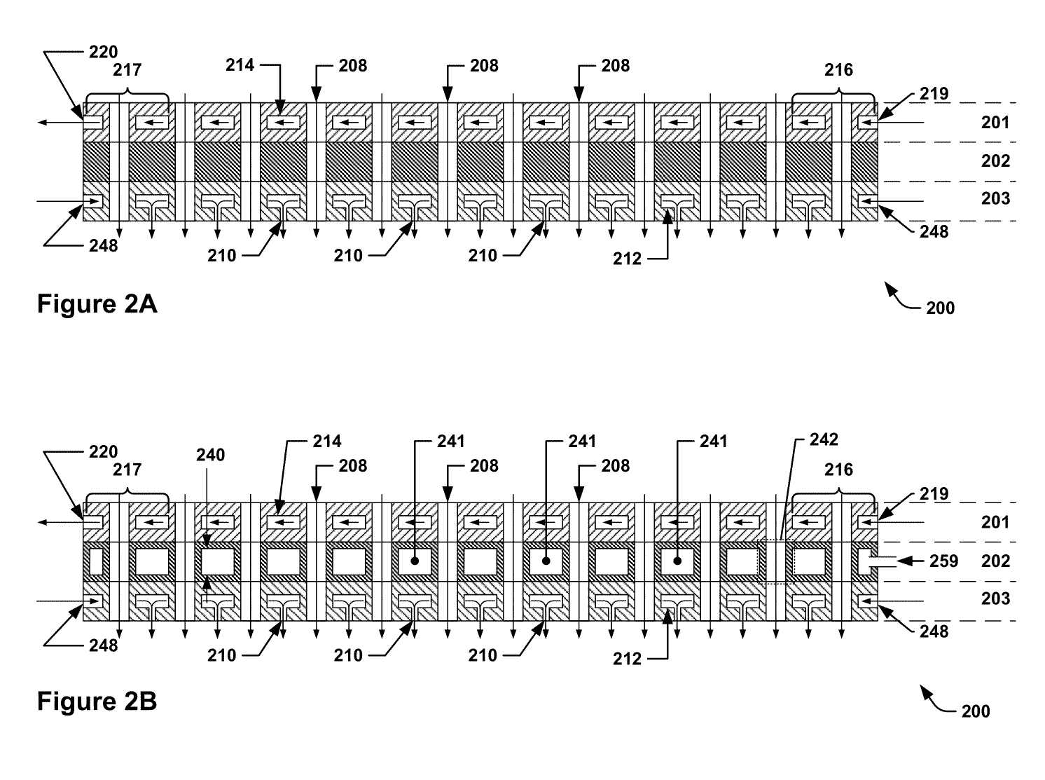

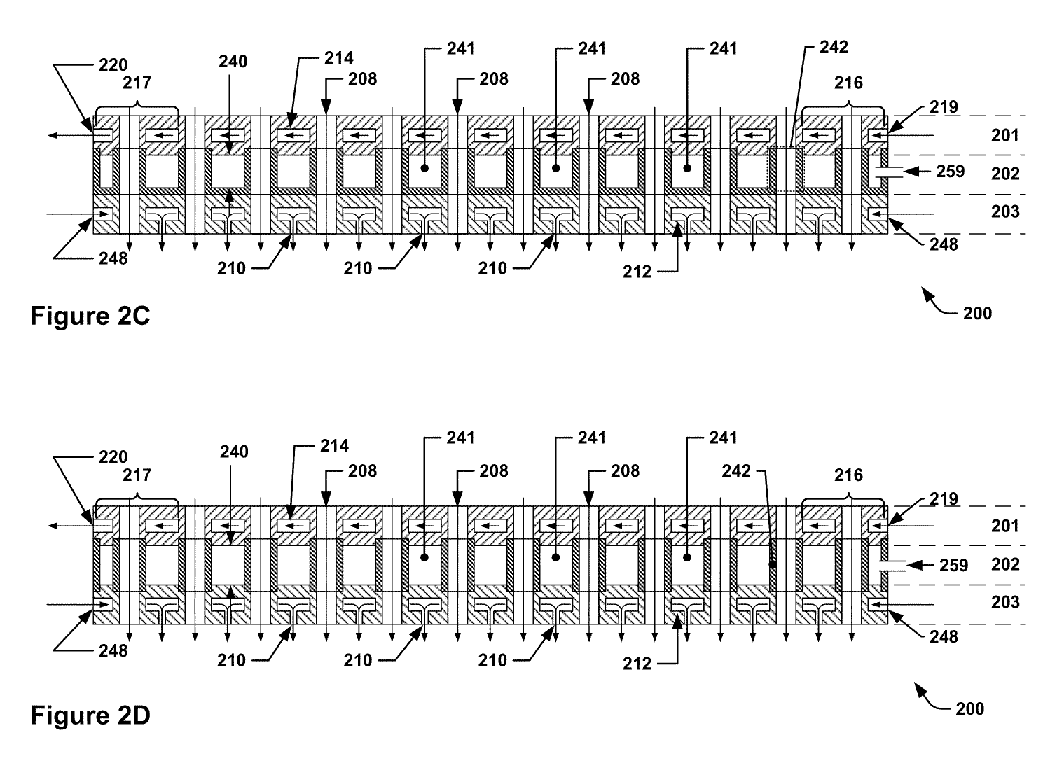

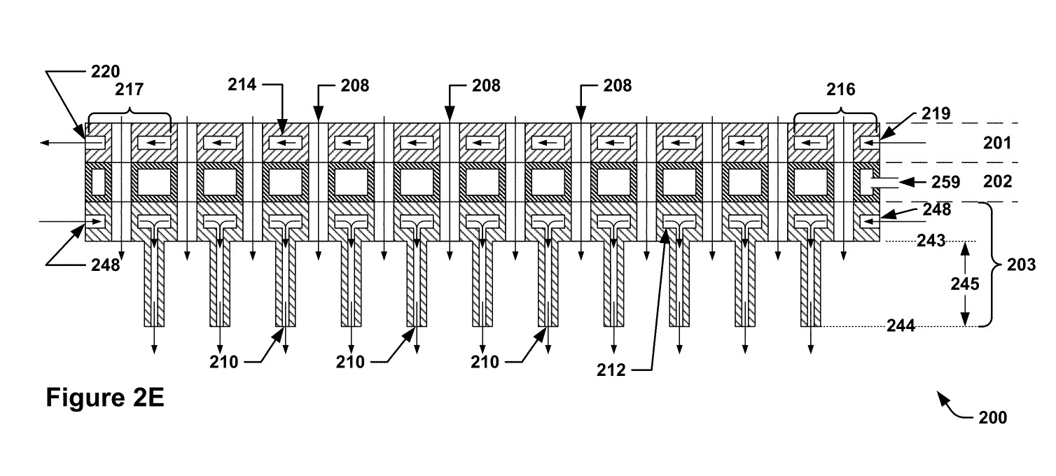

FIGS. 2A through 2E depict high-level schematics of various faceplate assemblies. Various aspects of faceplate assemblies in the context of this disclosure are discussed. Generally speaking, the radical diffuser plate and the precursor delivery plate of a faceplate assembly may be kept at different temperatures to facilitate improved processing environments. For example, the radical diffuser plate may be kept at a substantially lower temperature than the precursor delivery plate to improve radical delivery efficiency. This is because radicals exhibit increased tendencies to recombine with a surface upon collision when the surface is warmer than when the surface is colder. By decreasing the radical diffuser plate temperature, radicals colliding with the radical diffuser plate are less likely to recombine with the radical diffuser plate, leaving more radicals to flow through the radical through-holes. At the same time, cooling the precursor delivery plate could cause process gases delivered by the precursor delivery plate to undesirably condense. To prevent such condensation, the precursor delivery plate may be heated, either directly, e.g., via heating elements or fluid heat exchangers, or indirectly, e.g., via thermal contact with a higher-temperature component such that the precursor delivery plate remains above the vaporization temperature of the precursor.

In some implementations, the radical diffuser plate, as well as other components, may be wholly or partially coated with materials to inhibit or prevent radical recombination. For example, the side of the radical diffuser plate facing the radical source volume may be provided with an aluminum nitride, quartz, or sapphire coating.

The thermal isolator may be interposed between the radical diffuser plate and the precursor delivery plate to control heat flow between these two components. The thermal isolator may thus be generally described as a component or components that are arranged to hinder heat flow between the precursor delivery plate and the radical diffuser plate without substantially impacting radical delivery efficiency through the faceplate assembly.

In the implementations shown in FIGS. 2A through 2E, the faceplate assemblies 200 all include major components including a radical diffuser plate 201, a thermal isolator 202, and a precursor delivery plate 203. The faceplate assemblies also include a pattern of radical pass-through holes 208 and a pattern of gas delivery holes 210. The radical pass-through holes 208 pass completely through the faceplate assembly 200, whereas the gas delivery holes 210 pass through part of the precursor delivery plate 203 and exit the same side of the precursor delivery plate 203 as the radical pass-through holes 208 do. The gas delivery holes 210 are fluidly connected with one or more internal gas distribution passages 212. The internal gas distribution passages 212 may be fluidly connected with one or more precursor gas inlets 248 that flow a process gas, e.g., a precursor gas, into the precursor delivery plate 203 and out through the gas delivery holes 210. The radical diffuser plate 201 may include passages 214 that may each be fluidly connected to one or more inlets 219 at a first end 216 and to one or more outlets 220 at a second end 217. Coolant may be circulated through the radical diffuser plate 201 via the passages 214 to transfer heat from the radical diffuser plate 201 and lower the radical diffuser plate's temperature. The coolant may be provided from an external source, such as a coolant supply or heat exchanger system.

FIG. 2A depicts a high-level schematic of one example of a tri-partitioned faceplate assembly featuring a perforated plate that acts as a thermal isolator. In this implementation, the thermal isolator 202 takes the form of a layer of material that is sandwiched between the radical diffuser plate 201 and the precursor delivery plate 203. The material used for the thermal isolator 202 may be a material with a relatively low thermal conductivity (as compared to the thermal conductivities of the radical diffuser plate 201 and the precursor delivery plate 203) while still maintaining compatibility with process chemistries and low reactivity with radicals. For example, the thermal isolator 202 may be made from a material such as a low-K ceramic, quartz, various low-thermal conductivity plastics, e.g., polyimides, or stainless steels (coated to protect them from the chemical environment of a semiconductor processing chamber), e.g., 300-series stainless, whereas the radical diffuser plate 201 and the precursor delivery plate 203 may be made from materials with thermal conductivities an order of magnitude or more higher, e.g., aluminum alloys. The radical through-holes 208 may pass through the thermal isolator 202. As can be seen, the radical through-holes 208 maintain a substantially uniform cross-section as they pass through the radical diffuser plate 201, the thermal isolator 202, and the precursor delivery plate 203. This helps reduce the surface area within each radical through-hole 208 that radicals travelling through the radical through-hole 208 may encounter, reducing the chances that such radicals will recombine with the side walls of the radical through-hole.

FIG. 2B depicts a high-level schematic of one example of a tri-partitioned faceplate assembly featuring a hollow plate that acts as a thermal isolator. In this implementation of a faceplate assembly 200, the thermal isolator 202 may be largely hollowed out to form an internal free volume 241 that may be pumped down to a vacuum. The free volume 241 may substantially define a gap 240 within the thermal isolator 202; in some implementations, as will be seen, the gap 240 may be between the radical diffuser plate 201 and the precursor delivery plate 203 or between either the radical diffuser plate 201 or the precursor delivery plate 203 and a surface of the thermal isolator 202. Tubular structures 242 may substantially fluidly isolate the radical through-holes 208 from the internal free volume 241. Heat flow through the thermal isolator is, due to the presence of the vacuum in the internal free volume 241, effectively limited to radiative heat transfer mechanisms through the free volume 241 and limited conduction through the material of the tubular structures 242. To reduce the amount of conductive heat flow in this implementation, the thermal isolator 202, as with the thermal isolator 202 of FIG. 2A, be made of a low-K material.

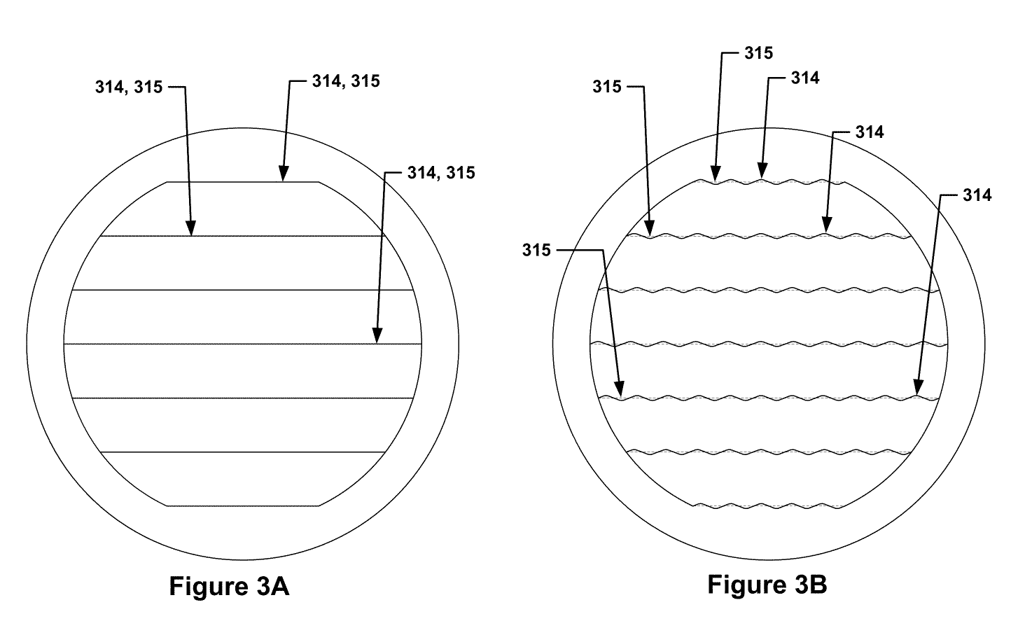

The free volume 241 may be pumped down to a vacuum via a vacuum port 259 connected with a vacuum pump or may be fluidly connected with the larger volume of the process chamber housing the faceplate assembly 200, e.g., via vacuum ports (not shown in FIG. 2B, but see FIGS. 3A and 3B) leading through the faceplate assembly 200 and to the wafer reaction area. Since the wafer reaction area may be held to vacuum conditions (aside from the addition of small amounts of process gases that are provided through the faceplate assembly 200), this may also serve to maintain the free volume 241 at similar atmospheric conditions.

FIG. 2C depicts a high-level schematic of one example of a tri-partitioned faceplate assembly featuring an alternate hollow plate thermal isolator design. This implementation is similar to that described with reference to FIG. 2B, except that the thermal isolator 202 does not fully define the free volume 241. Instead, the thermal isolator 202 includes a plate with the tubular structures 242 protruding from it at each radical through-hole 208 location. The gap 240, in this implementation, is defined by the distance between the radical diffuser plate 201 and the plate in the thermal isolator 202. The tubular structures 242 may extend into recesses in the radical diffuser plate 201. In some implementations, the tubular structures 242 may simply butt up against the radical diffuser plate 201 and not extend into such recesses. In some other implementations, the tubular structures 242 may be separated from the radical diffuser plate 201 by a small gap, i.e., a hermetic seal between the tubular structures 242 and the radical diffuser plate 201 is not necessary. Such a small gap may be small enough that flow conductance between the tubular structures 242 and the radical diffuser plate 201 is substantially smaller than flow conductance through the radical through-holes. A vacuum port 259 may be used to pump down the free volume 241 within the thermal isolator 202 to further reduce thermal conductivity of the thermal isolator 202.

FIG. 2D depicts a high-level schematic of one example of a tri-partitioned faceplate assembly featuring a thermal isolator featuring a plurality of discrete tubes. In this implementation, the thermal isolator 202 does not exist as a single, definable part. Instead, it may be formed by a collection of smaller parts interposed between the radical diffuser plate 201 and the precursor delivery plate 203. For example, one or both of the radical diffuser plate 201 and the precursor delivery plate 203 may include recesses allowing a discrete tubular structure 242 to be inserted into the radical diffuser plate 201 and/or the precursor delivery plate 203. A circumferential outer wall may provide structural support between the radical diffuser plate 201 and the precursor delivery plate 203 and define the outer limit of the free volume 241. The circumferential outer wall and the tubular structures in this implementation may be made from the same or different materials. For example, the circumferential outer wall may be made from aluminum oxide, whereas the tubular structures may be made from quartz.

FIG. 2E depicts a high-level schematic of one example of a tri-partitioned faceplate assembly featuring offset gas distribution hole and radical through-hole exits. The implementations discussed above with respect to FIGS. 2A through 2D have focused on various thermal isolator implementations. The implementation shown in FIG. 2E utilizes a thermal isolator 202 similar to that shown in FIG. 2B, although other types of thermal isolators 202, as described above, may be used as well. In FIG. 2E, however, the gas delivery plate 203 features a different geometry than the gas delivery plates 203 shown in FIGS. 2A through 2D. The gas delivery plate 203 of FIG. 2E has radical through-holes 208 that exit the gas delivery plate 203 in a first plane 243 that is offset a first non-zero distance 245 from a second plane 244 through which the gas delivery holes 210 exit the gas delivery plate 203.

For example, the gas delivery plate 203 may be a substantially flat plate with a small tube protruding from the flat plate at each gas delivery hole 210 location. The offset between the exit planes of the gas delivery holes 210 and the radical through-holes 208 may allow for the radical gas flow from the radical through-holes to reach substantially fully-developed flow conditions before the precursor gas is introduced to the radical gas. By physically offsetting the exit planes for the respective gases, the radical gas is provided with sufficient time to reach fully-developed flow. In some implementations, the offset may be larger than 0.25″. In some further implementations, the offset may be between 0.25″ and 3″. In some additional further implementations, the offset may be between 3″ and 12″.

It is to be understood that the various concepts outlined above for the radical diffuser plate 201, the thermal isolator 202, and the gas delivery plate 203 may be assembled in various permutations different from those shown. For example, the gas delivery plate 203 with the non-co-planar exit planes from FIG. 2E may be used with the radical diffuser plate 201 and thermal isolator 202 from FIG. 2A. Similar substitutions may be made with regard to the other FIGS. 2B through 2D, with appropriate modification.

It is to be further understood that while the precursor delivery plate 203 shown in the Figures features only a single set of gas delivery holes, some implementations may feature a precursor delivery plate 203 with multiple sets of gas delivery passages and corresponding gas delivery holes. For example, the precursor delivery plate 203 may be configured with two sets of gas delivery passages and two corresponding sets of gas delivery holes that are fluidly isolated from one another within the gas delivery plate 203.

For the various plates with internal cooling passages, such as the radical diffuser plate 201 and some implementations of the thermal isolator 202, the cooling passages may traverse the plates within which they are located in a serpentine or circuitous route. In some other implementations, the cooling passages may follow a substantially straight path. FIG. 3A depicts a schematic showing substantially straight cooling channel paths. FIG. 3B depicts a schematic also showing substantially straight cooling channel paths. As can be seen in FIG. 3A, a cooling passage 314 may follow a straight path 315; such passages may be, for example, the product of cross-drilling a plate with a gun drill. As can be seen in FIG. 3B, the cooling passage 314 may deviate from the straight path 315, e.g., by weaving back and forth across the straight path 315, while still generally extending along the straight path 315. Thus, reference to passages that follow paths that are parallel to a reference plane, for example, may be understood to include passages that substantially follow a straight path, as shown in FIGS. 3A and 3B, that is parallel to the reference plane.

Reference is now made to various, more-detailed Figures depicting further examples of faceplate assemblies and components therein per the concepts outlined in this disclosure.

FIG. 4A depicts an isometric view of one example of a tri-partitioned faceplate assembly. A faceplate assembly 400 is shown that features a radical diffuser plate 401, a precursor delivery plate 403, and a thermal isolator 402 interposed between the radical diffuser plate 401 and the precursor delivery plate 403. The thermal isolator 402 is somewhat difficult to see in this view, but is more visible in later Figures.

The faceplate assembly may feature a pattern of radical through-holes 408 distributed across a substantially circular region about a center axis 431. The radical through-holes 408 may have hole center axes 409 that are substantially normal to the radical diffuser plate 401. The radical through-holes may have a total sidewall area representing the sum of the sidewall areas (including sidewalls of portions of the radical through holes 408 located in the thermal isolator 402 and the precursor delivery plate 403) of all of the radical through-holes 408 and the portion of the radical diffuser plate 401 that forms part of the boundary of the radical source volume may have a cross-sectional area, not including the cross-sectional areas of the radical through-holes 408. In some implementations, the ratio of the total sidewall area of the radical pass-through holes 408 to the cross-sectional area discussed above may be less than 1 to 1.5.

In some implementations, the length to diameter ratio of the radical through-holes 408 may be greater than 2:1 and the length may be greater than 0.25″ to help prevent back-diffusion of gases delivered by the faceplate assembly 400 into faceplate assembly 400 via the gas delivery holes 410 or the radical through-holes 408. In some implementations, the length to diameter ratio of the radical through-holes 408 may be between 7:1 and 10:1. The radical through-holes 408 may have a nominally uniform cross-sectional area perpendicular to the hole center axes through the faceplate assembly 400. In some implementations, there may be some variation in cross-sectional area, e.g., flaring of the radical through-holes 408 where they enter and exit the faceplate assembly 400.

The radical diffuser plate 401 and the precursor delivery plate 403 that are shown in FIG. 4A are multi-part designs (although the multi-part aspect is only shown with respect to the radical diffuser plate. For example, the radical diffuser plate 401 is formed from a substantially circular inner portion with four arcuate outer portions that are welded to the outer perimeter of the inner portion at weld areas 447. This allows cross-passages to be drilled through the width of the inner portion and for the cross-passages to then be capped by the outer portions, forming a sealed interior space for gas or fluid flow. The radical diffuser plate 401 may also include one or more seal interfaces 446 that may be configured to seal the radical diffuser plate 401 to, for example, a back cover, adapter, plasma dome, or other mating surface. Further seal interfaces 446 may be located on other parts as well, such as on the thermal isolator 402 or the precursor delivery plate 403 to seal the interfaces between the radical diffuser plate 401, the thermal isolator 402, and the precursor delivery plate 403.

A first inlet 423 and a second inlet 427 may fluidly communicate with a first outlet 424 and a second outlet 428, respectively, via cooling passages internal to the radical diffuser plate 401. Similarly, one or more precursor gas inlets 448 may be in fluid communication with one or more internal gas distribution passages in the precursor delivery plate 403.

FIG. 4B depicts an isometric view of the faceplate assembly of FIG. 4A with multiple portions cut away for viewing of interior features. As can be seen, the radical through-holes 408 pass entirely through the radical diffuser plate 401, the thermal isolator 402, and the precursor delivery plate 403 and, in doing so, maintain substantially uniform cross-sections normal to center axes 409. Also visible in FIG. 4B is a passage 414 that is one of several such passages 414 in a network of first internal cooling passages 413. As can be seen, a first end 416 of the passage 414 may be fluidly connected with a coolant plenum 450 that, as will be seen in FIG. 4C, is fluidly connected with a first inlet 423. A second inlet 427 may be fluidly connected with a different coolant plenum 450 and, in turn with the first ends 416 of other passages 414 (not shown in this Figure). In some implementations, the first inlet 423 and the second inlet 427, or a single common inlet, may be connected with a common coolant plenum 450 that is connected with the first ends 416 of the passages 414. Second ends 417 (not shown in FIG. 4B, but visible in FIG. 4C, discussed below) of the passages 414 may also be connected to a coolant plenum or coolant plenums 450 that may, in turn, be connected to a first outlet 424 and a second outlet 428 or, in some implementations, to a single common coolant plenum 450 and/or to a single common outlet. Other cooling solutions sufficient to provide substantially uniform cooling across the radical diffuser plate 401, e.g., less than a ˜1-2° C. temperature differential across the portion of the radical diffuser plate that may be in contact with radicalized gas during ordinary process conditions, may be used as well and are considered to be within the scope of this disclosure.

The precursor delivery plate 403 may, in some respects, have some features similar to those in the radical diffuser plate 401. For example, the precursor delivery plate 403 may have a precursor plenum 451 and internal gas distribution passages 412 that may be substantially similar in some respects to the coolant plenums 450 and the passages 414. The precursor delivery plate 403 may also have one or more precursor gas inlets 448 that are configured to introduce precursor gas into the precursor plenum 451. In contrast to the radical diffuser plate 401, however, fluids, e.g., precursor gas, that are flowed into the precursor plenum 451 and the internal gas distribution passages 412 may not exit the precursor delivery plate 403 via outlets similar to the first outlet 424 and the second outlet 428, but may instead flow out of a pattern of gas delivery holes 410 that are fluidly connected with the internal gas distribution passages 412. The gas delivery holes 410 may have hole center axes 411 that are parallel to the center axes 409 of the radical through-holes 408. The gas delivery holes 410 may be substantially smaller in cross-section than the radical through-holes 408. In other implementations, however, the structure of the radical diffuser plate and the precursor delivery plate 403 may differ to a much greater extent than as shown in FIG. 4B.

FIG. 4C depicts an isometric exploded view of the faceplate assembly of FIG. 4A with some components having portions cut away for viewing of interior features. In FIG. 4C, the top half of the radical diffuser plate 401 has been removed to allow passages 414 to be seen. The top half of the precursor delivery plate 403 has also been removed for similar reasons.

The radical diffuser plate 401 may have a first side 406 (which, in FIG. 4C, is not directly visible since it is on the portion of the radical diffuser plate 401 that has been cut away—the first side 406 is also indicated in FIG. 4B) and a second side 407 opposite the first side.

Also visible are coolant plenums 450, that, in this implementation, are arcuate interior spaces, each occupying a different quadrant of the radical diffuser plate 401. The coolant plenums 450 and passages 414 located on one side of a reference plane 418 may be fluidly isolated within the radical diffuser plate 401 from the coolant plenums 450 and passages 414 located on the other side of the reference plane 418. This plenum/passage arrangement may allow for relatively high coolant flow rates and may provide substantially uniform temperature differentials across the width of the radical diffuser plate, e.g., less than about 1° C. of temperature difference. Each passage 414 may be connected to a cooling plenum 450 at a first end 416 and to a different cooling plenum 450 at a second end 417. A temperature sensor hole 449 may be provided such that a temperature sensor, e.g., a thermocouple or other temperature-measuring probe (not shown), may be located near the center of the radical diffuser plate 401 for monitoring of the temperature in the radical diffuser plate 401.

With respect to the precursor delivery plate 403, it may be observed that, in this implementation, a single precursor plenum 451 is provided that substantially extends around the perimeter of the precursor delivery plate 403. A precursor gas inlet 448 may be provided that is configured to feed precursor gas to the precursor plenum 451. Precursor gas from the precursor plenum 451 may flow into the internal gas distribution passages 412 and, from the internal gas distribution passages 412, out of the precursor delivery plate via the gas delivery holes 410. The gas delivery holes 410 may be distributed in across the precursor delivery plate 403 in a manner relatively similar to the manner in which the radical pass-through holes 408 are distributed. It is to be understood that other implementations may utilize different holes patterns for both the radical through-holes 408 and the gas delivery holes 410. The radical through-holes 408 may be positioned so as to be fluidly isolated from the internal gas distribution passages 412, the gas delivery holes 410, the coolant plenums 450, the precursor plenums 451, and the passages 414 within the faceplate assembly 400.

The precursor delivery plate 403 may, similar to the radical diffuser plate 401, have a first side 404 (again, this side is not directly visible in FIG. 4C due to the cutaway) and a second side 405. Generally speaking, the first side 404 of the precursor delivery plate 403 may face the second side 407 of the radical diffuser plate 401, with the thermal isolator interposed between the first side 404 and the second side 407.

As discussed earlier in this disclosure, different types of radical diffuser plates 401, thermal isolators 402, and precursor delivery plates 403 may be used in various stacked arrangements to provide faceplate assemblies 400. FIGS. 4A through 4C depict a faceplate assembly 400 with a radical diffuser plate 400 with unidirectional coolant flow through the passages 414.

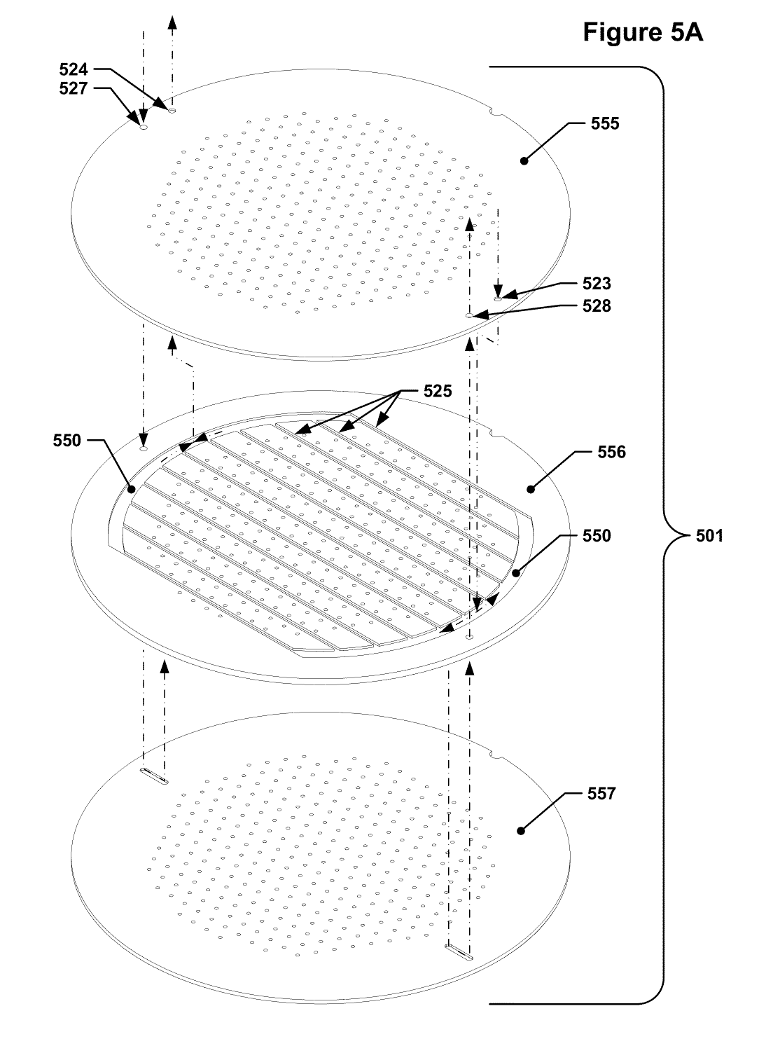

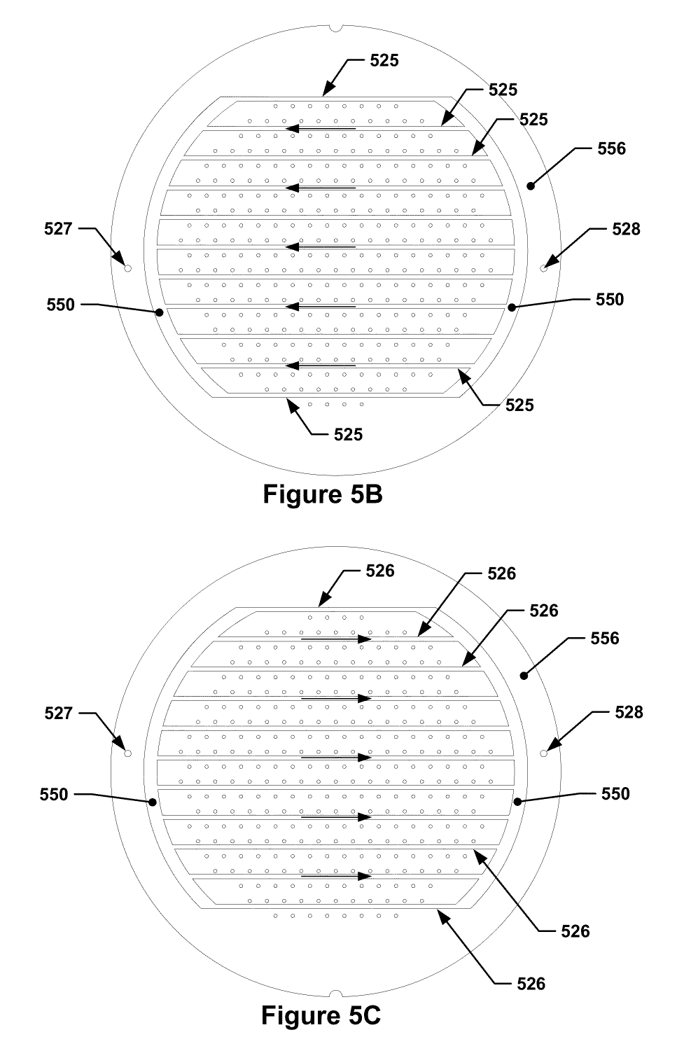

FIG. 5A depicts an isometric exploded view of one example of a radical diffuser plate with opposing flow cooling channels. In FIG. 5A, a radical diffuser plate 501 may be formed by a stack of three major components: a top plate 555, a midplate 556, and a bottom plate 557. These plates may be clamped together or may be held together through more permanent measures, such as through brazing. The top plate 555 may have a first inlet 523 and a second inlet 527. The first inlet 523 may pierce the top plate 555 and be in fluid communication with a coolant plenum 550 (shown on the right in FIG. 5A) via a slot (not shown, but similar to the slots shown on the top surface of the bottom plate 557) in the bottom surface of the top plate 555. Coolant flowed into the coolant plenum 550 via the first inlet 523 may then flow through first passages 525 in the midplate 556 and into another coolant plenum 550 before flowing, via another slot, from the first outlet 524.

Also visible in FIG. 5A are a second inlet 527 and a second outlet 528, both of which are in fluid communication with second passages 526 (not visible in this view, but see FIG. 5C) on the underside of the midplate 556 via the slots visible in the bottom plate 557. Arrows are included in FIG. 5A to convey fluid flow directions into/out of each inlet/outlet and plenum.

FIG. 5B depicts a first side of the midplate of the radical diffuser plate of FIG. 5A. FIG. 5C depicts a second side of the midplate of the radical diffuser plate of FIG. 5A. The first side shown in FIG. 5B corresponds to the visible side of the midplate 556 in FIG. 5A. Flow arrows indicate that fluid flow in the first passages 525 is from right to left. The second side shown in FIG. 5C is on the opposite side of the midplate 556 from the first side. Flow arrows indicate that fluid flow in second passages 526 is from left to right. Thus, coolant may be flowed in a first direction within the first passages and in a second direction opposite the first direction in the second passages. This may produce a more uniform temperature distribution across the portion of the radical diffuser plate 501 containing the radical through-holes 508.

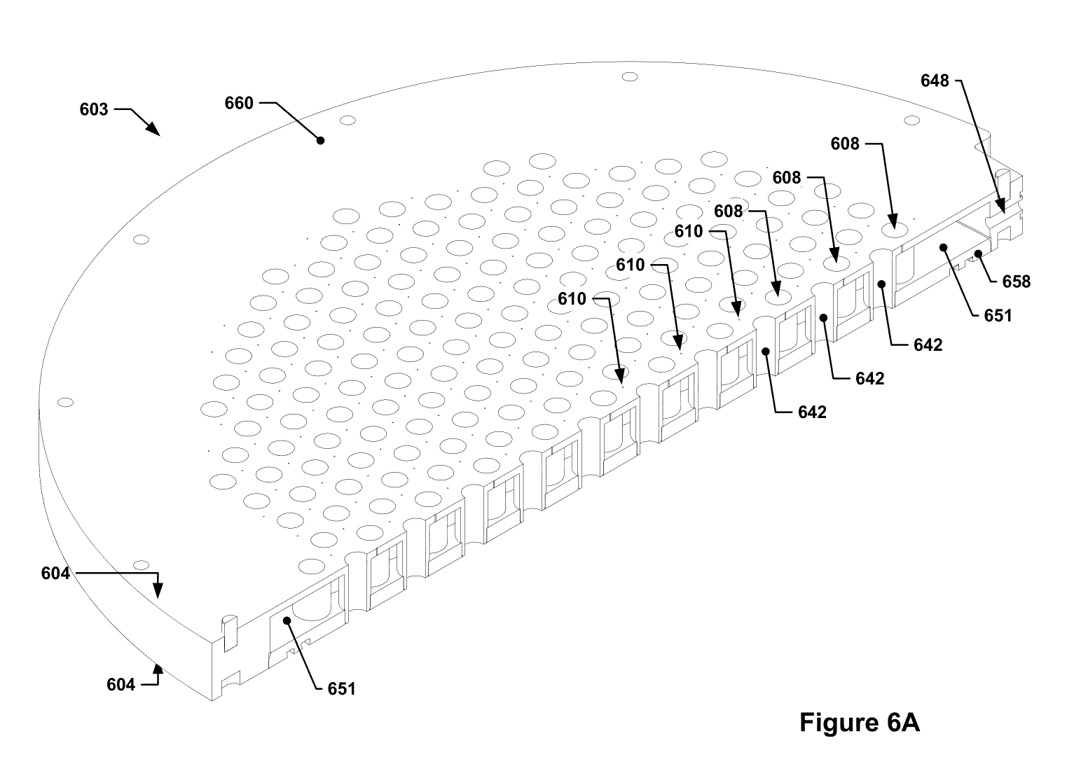

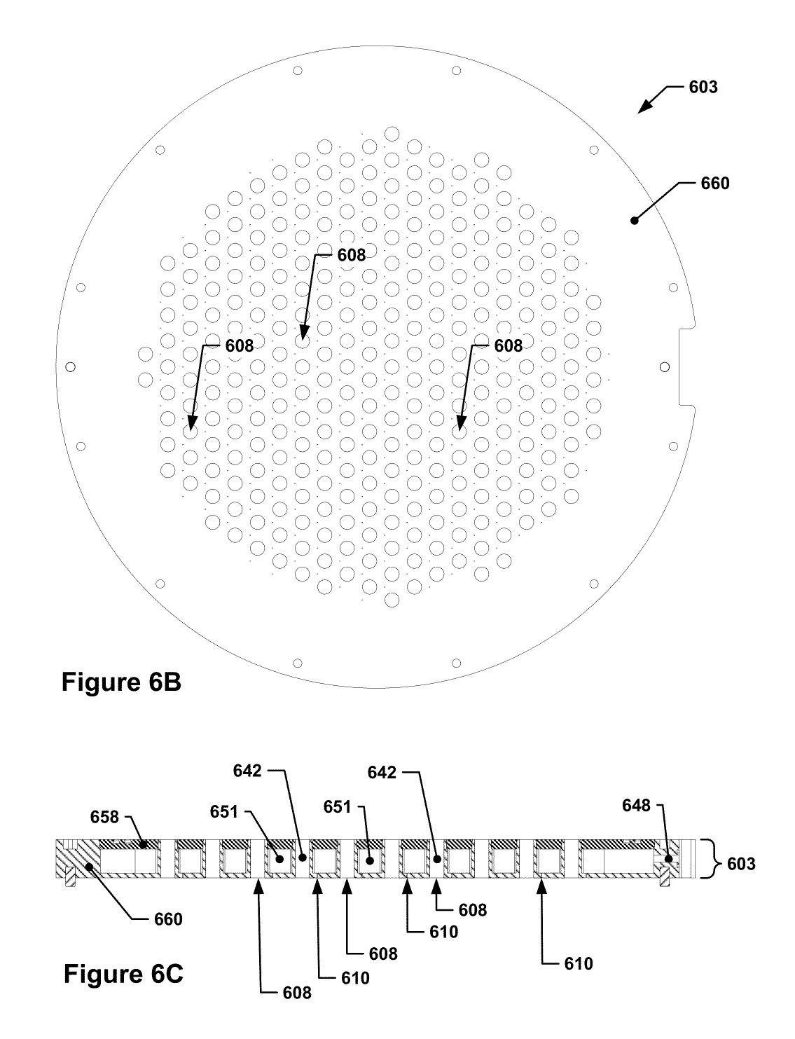

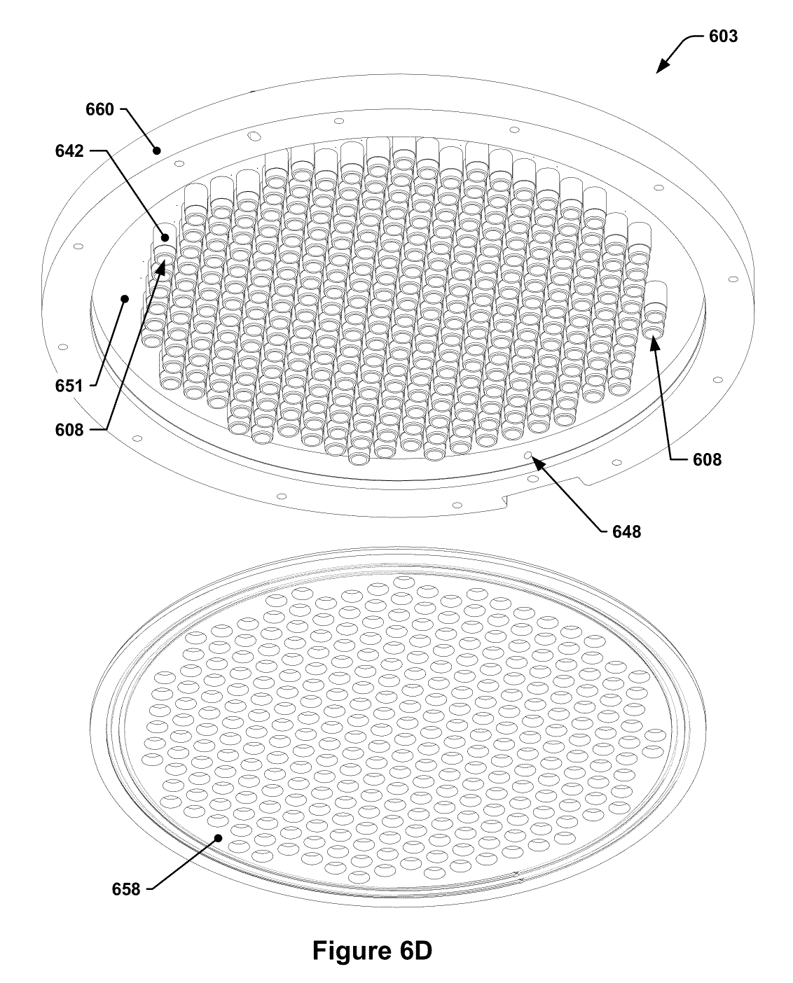

FIG. 6A depicts an isometric section view of one example of a precursor delivery plate. FIG. 6A's precursor delivery plate 603 is similar to the concept shown in FIG. 2C, and includes a main plate 660 that includes a number of tubular structures 642 that protrude from the main plate 660 and into a cap plate 658. Each tubular structure 642 may include radical through-hole 608 that passes through it. The main plate 660 and the cap plate 658 may be offset from one another by a gap to form a precursor plenum 651. In this implementation, the precursor plenum 651 not only includes a perimeter volume around the radical through-holes 608, but also includes the interstices between the tubular structures 642, thus replacing the need for discrete gas distribution channels. A pattern of gas delivery holes 610 may be present on a second side of the gas delivery plate 603 and in fluid communication with the precursor plenum 651 (it is to be understood that the precursor delivery plate 603 is shown “upside down” in this Figure since the gas delivery holes 610 would normally be pointing down towards a wafer reaction area during use).

FIG. 6B depicts a bottom view of the precursor delivery plate of FIG. 6A. As can be seen in this view, the gas delivery holes 610 and the radical through-holes are arranged in substantially evenly distributed manner across an interior portion of the gas delivery plate 603. FIG. 6C depicts a side section view of the precursor delivery plate of FIG. 6A. This view shows some of the details from FIG. 6A in more clarity. FIG. 6D depicts an exploded reverse isometric view of the precursor delivery plate of FIG. 6A. This view shows that the tubular structures 642 may have shoulders or tapered edges along their outer surfaces, although it should be noted that the interior surfaces shown reflect a constant cross section matching the radical through-hole cross section. In practice, the tubular structures 642 may include a variety of features to facilitate manufacturing or assembly, e.g., rounded or chamfered exterior edges.

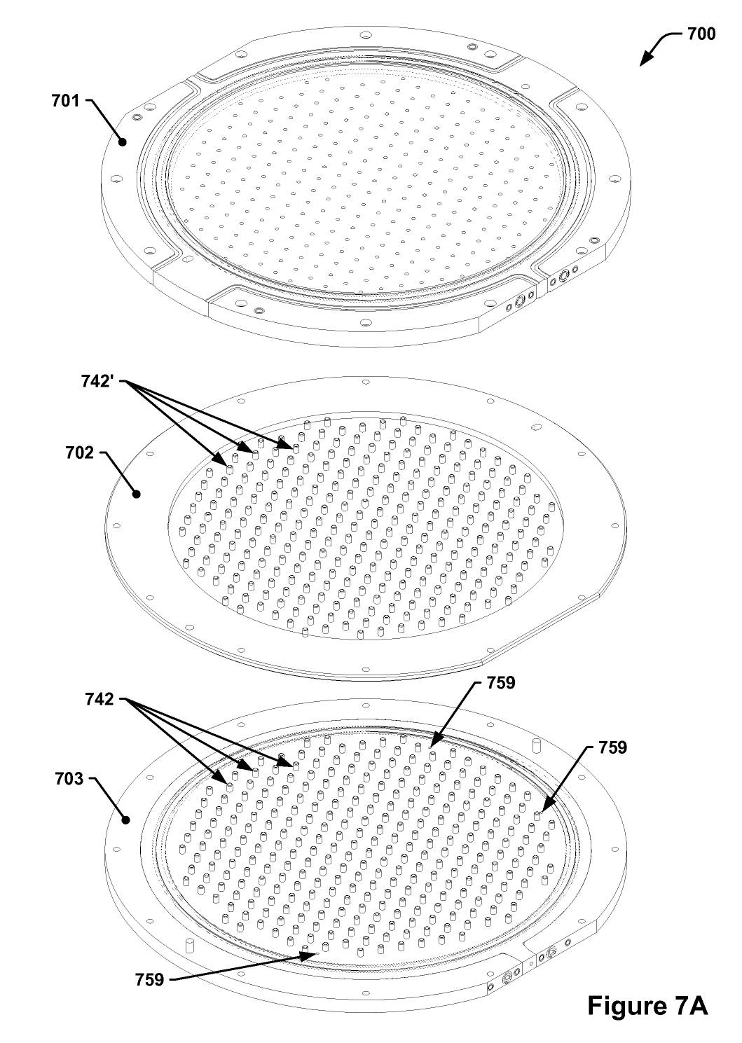

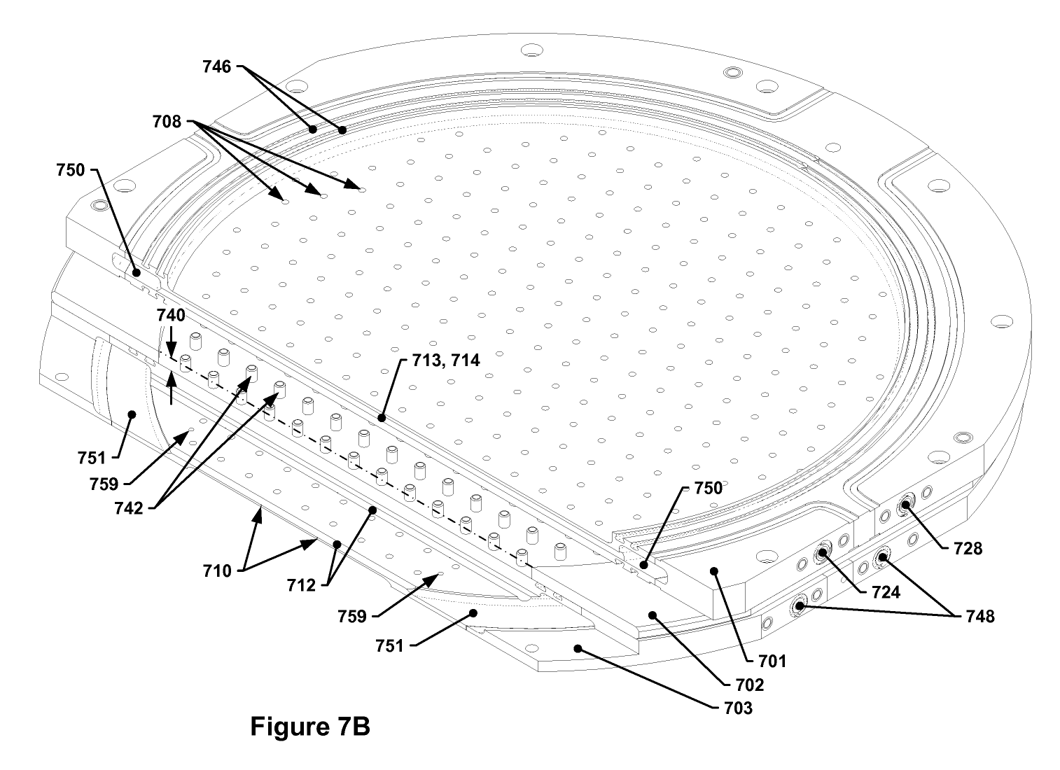

FIG. 7A depicts an isometric exploded view of one example of a thermal isolator. In FIG. 7A, a radical diffuser plate 701 similar to the radical diffuser plate 401 is shown. A thermal isolator 702 and a precursor delivery plate 703 may be provided, however, that are different from the thermal isolator 402 and the precursor delivery plate 403. In this implementation, tubular structures 742 protrude out of a first side 704 of the precursor delivery plate 703 and into a cylindrical volume within the thermal isolator 702. In FIG. 7A, tubular structure placeholders 742′ depict the locations of the tubular structures 742 within the thermal isolator 702 when the faceplate assembly 700 is fully assembled. Thus, the various components that form portions of the radical diffuser plate 701, the thermal isolator 702, and/or the precursor delivery plate 703 may be supported by or attached to other layers of the faceplate assembly 700 and then positioned appropriately during assembly. Also visible in FIG. 7A are vacuum ports 759, which, in this implementation, are simply holes that allow the cylindrical volume within the thermal isolator 702 to vent through the precursor delivery plate 703 to the wafer reaction area or the surrounding process chamber volume (thus allowing the pressure in the cylindrical volume to maintain equilibrium with the pressure conditions within the semiconductor processing chamber, e.g., maintain a vacuum environment).

FIG. 7B depicts an isometric view of the thermal isolator of FIG. 7A with some portions cut away for viewing of interior features. In FIG. 7B, the radical diffuser plate is shown with a chord section cut that bisects one of several passages 714 that span between coolant plenums 750 and that are part of a network of first internal cooling passages 713. Radical through-holes 708 may pass through the radical diffuser plate 701, and seal interfaces 746 may be provided to allow the faceplate assembly 700 to be sealed, for example, to a plasma dome structure or other structure (not shown) that may, in conjunction with the faceplate assembly 700, substantially define a remote plasma volume. A first outlet 724 and a second outlet 728 may allow for coolant to exit the interior of the radical diffuser plate 701.

The thermal isolator 702 is shown with a different chord section cut. As can be seen, tubular structures 742 protruding from the precursor delivery plate 703 may protrude into a volume defined by a gap 740 between the radical diffuser plate 701 and the precursor delivery plate 703.

The precursor delivery plate 703 is shown with stepped chord cuts, i.e., the precursor delivery plate 703 is shown with a chord section cut to a depth approximately halfway through its thickness, and with a smaller chord section cut through its remaining thickness. A precursor plenum 751 is visible, as are two internal gas distribution passages 712 and two gas delivery holes 710. Precursor gas inlets 748 may be fluidly connected with the internal gas distribution passages 712.

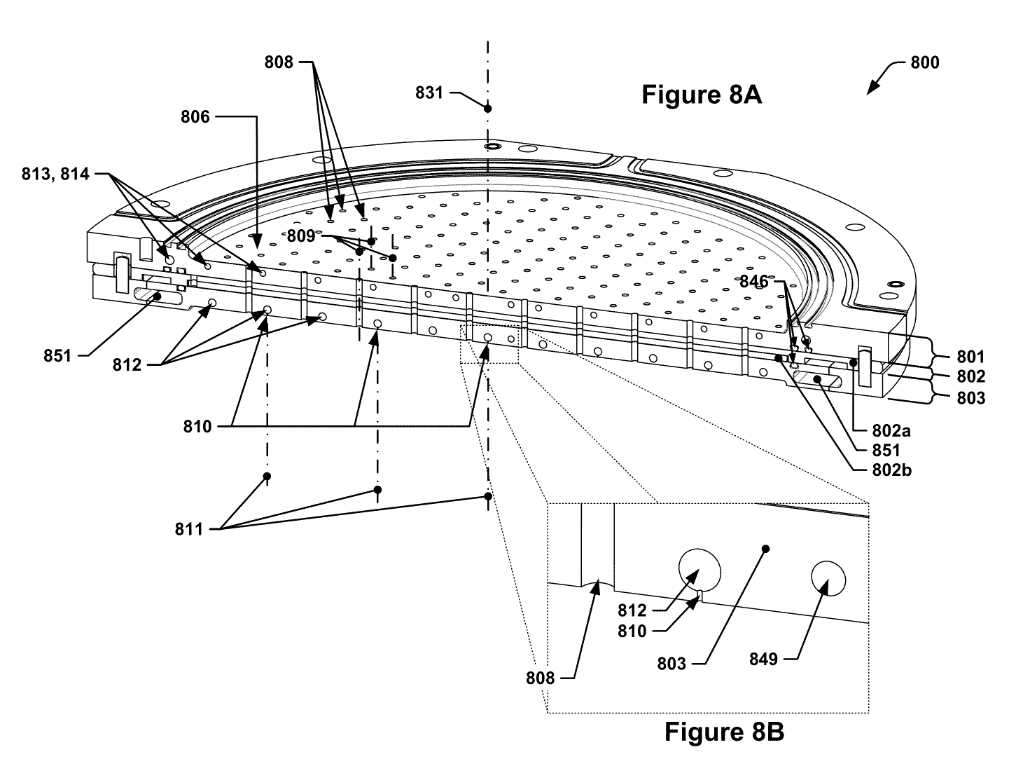

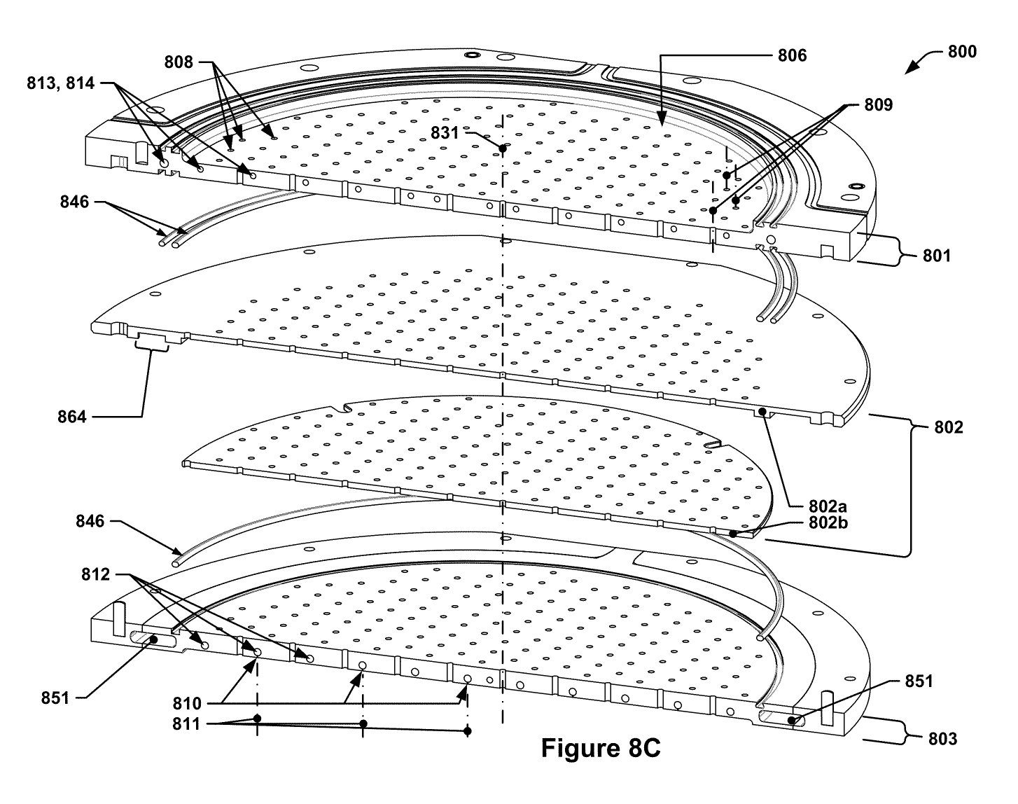

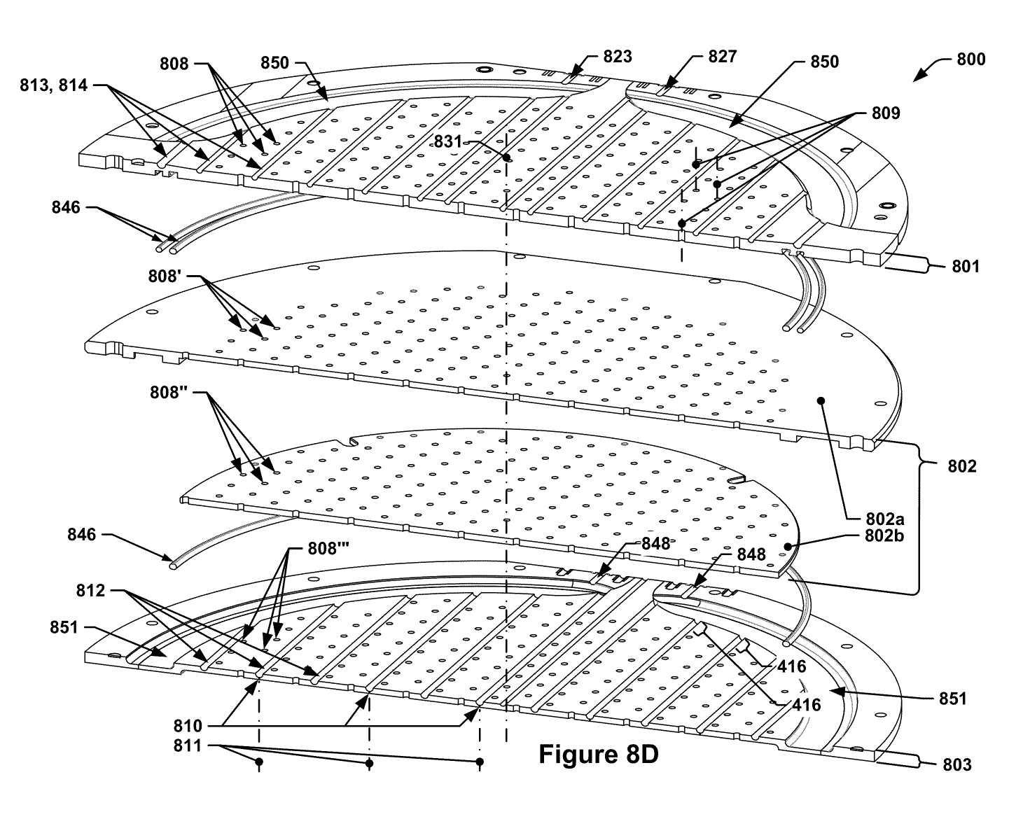

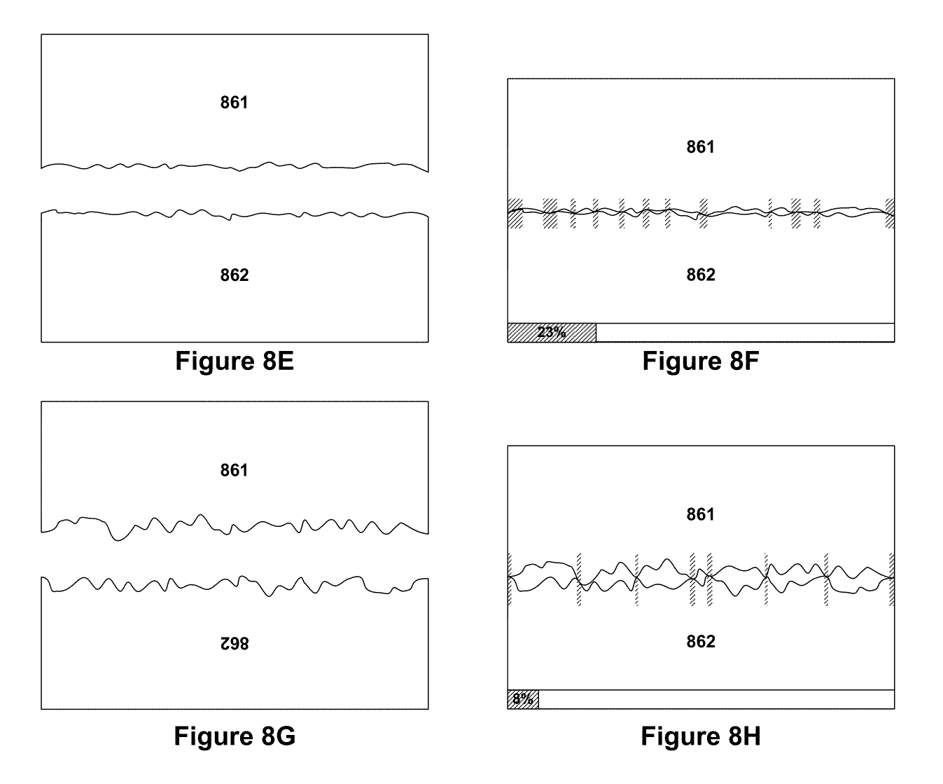

FIG. 8A depicts a dimetric section view of one example of a tri-partitioned faceplate assembly. FIG. 8B depicts a detail view of a portion of the example sectioned tri-partitioned faceplate assembly of FIG. 8A. FIG. 8C depicts a dimetric section exploded view of the example tri-partitioned faceplate assembly of FIG. 8A. FIG. 8D depicts another dimetric exploded section view of the example tri-partitioned faceplate assembly of FIG. 8A with the upper portions of the radical diffuser plate and the precursor delivery plate removed to allow viewing of internal features.

Generally speaking, many of the features shown in FIGS. 8A through 8D are similar to those shown in FIGS. 4A through 4C. Elements in FIGS. 8A through 8D that are numbered with callouts having the same last two digits as similar structures in FIGS. 4A through 4C are to be understood to be substantially similar to the corresponding structures in FIGS. 4A through 4C, unless described differently herein. In the interest of avoiding repetition, the reader is referred to the earlier description of such elements with respect to FIGS. 4A through 4C with regard to FIGS. 8A through 8D.

As can be seen in FIG. 8A, a thermal isolator 802 is located between a radical diffuser plate 801 and a precursor delivery plate 803. In contrast to the thermal isolator 402 of FIGS. 4A through 4C, however, the thermal isolator 802 is a layered assembly having two separate parts, a first layer 802a and a second layer 802b, that are stacked together to form the thermal isolator 802. As shown, each layer may be at least large enough to include substantially all of the radical through-holes 808 (each radical through-hole 808 passes through the layers of the thermal isolator 802, as well as the radical diffuser plate 801 and the precursor delivery plate 803; the individual radical through-holes through each component are called out as 808′, 808″, etc.) present in the faceplate assembly 800. As shown, the second layer 802b is nestled inside of a recess in the first layer 802a. The recess may have a depth substantially equal to one half the nominal thickness of the first layer 802a, and the second layer 802b may have a thickness substantially corresponding to the recess depth. Accordingly, the thermal isolator 802 may fit within substantially the same envelope as the thermal isolator 402, although this is not required and other implementations may feature different overall envelopes.

Additionally, while the first layer 802a is shown as having a recess within which the second layer 802b fits, other implementations may feature layers that are substantially identical, e.g., two flat plates that stack on top of one another without one being recessed into the other. Various other implementations are contemplated as well, although a common feature of these other implementations may all feature multiple layers with discrete boundaries between them at least within the area of the faceplate assembly 800 containing the radical through-holes 808.

It is also to be understood that while the depicted example features two layers, other implementations may feature a thermal isolator 802 having more than two layers, e.g., three, four, or more layers. Such additional implementations are also within the scope of this disclosure.

The layers may have indexing features on them, e.g., three radial slots (only two are shown—the remaining is in the cut-away portion of the faceplate assembly 800) arrayed about the circumference of the second layer 802b in a radially-symmetric manner and three corresponding radial bosses arrayed about the interior of the recess of the first layer 802a in a similar manner, to ensure that the two (or more) layers, and the portions of the radical through holes on each such layer, of the thermal isolator 802 are aligned with one another. The indexing features may be configured, as shown, to allow the layers to expand and contract at different rates without incurring unacceptable thermal stress due to differential thermal expansions between the layers while simultaneously keeping the layers substantially centered with respect to one another.

The layers 802a and 802b may typically both be made from the same or similar materials, although in some implementations, different materials may be used if desired, e.g., if one of the layers is too difficult or costly to produce using a preferred material, then an alternate material may be used for that layer.

As noted previously, the first layer 802a and the second layer 802b have substantially the same thickness in the area in which the radical through holes 808 are located. While the layers (including additional layers beyond those shown) may have different thicknesses in this area, in many implementations, the layers may all have substantially equal thicknesses in this area. This may enhance the overall resistance of the thermal isolator 802 to failure. For example, if one layer was substantially thinner than the other layers (and all layers were of the same material), this could place the thinner layer at an increased risk of cracking or damage. By having each layer have substantially the same thickness in the area with the radical through-holes 808, this risk is not concentrated in any one layer, but may be substantially equal for all of the layers.

The materials used for the first layer 802a and the second layer 802b may be selected from a variety of low-thermal-conductivity materials, e.g., a dielectric material such as a low-K ceramic or quartz, various low-thermal conductivity plastics, e.g., polyimides, or stainless steels (coated to protect them from the chemical environment of a semiconductor processing chamber), e.g., 300-series stainless. For example, the first layer 802a and the second layer 802b may be made from aluminum oxide or aluminum nitride.

The present inventors have realized that a multi-layered thermal isolator 802 may, in the context of low-pressure semiconductor processing environments such as those in which the faceplate assembly 800 may be used, provide superior thermal resistance as compared with a single-layer thermal isolator such as is shown in FIGS. 4A through 4C, thus enabling a larger temperature differential between the radical diffuser plate 801 and the precursor delivery plate 803. This increased thermal resistance arises due to several reasons, which are explored more fully below.

First, the pressure under which such faceplate assemblies are typically operated is low enough that the density of any gas that is trapped in any gaps or non-contacting areas between the layers of the thermal isolator 802 is low enough that heat conduction through such gases does not significantly contribute to the overall heat conduction through the thermal isolator 802. While the heat conduction through such gas may also depend on the composition of such gas in addition to the pressure of the gas, generally speaking, the pressure may generally be the dominant determinant of the thermal conductivity through such gases. The pressure of such gases may, for example, be less than about 3 to 7 Torr, and in some implementations, the pressure may be less than about 1 to 0.1 Torr.

Second, the contact interface between each pair of adjacent layers in the thermal isolator 802 is not, due to the surface finish of the layers, a completely perfect contact interface, i.e., the layers are not in direct contact across 100% of their exposed area across the contact interface. For example, the surface roughness of many ceramic materials is generally rougher than may typically be achieved with other materials and, in the case of the layers of the thermal isolator 802, may be kept to an Rₐ value of at least 8 to 16 microinches or higher. In some implementations, the Rₐ value may be kept to a value of at least 4 to 8 microinches or higher. Due to this surface roughness, there may be much less actual direct contact between the layers than might occur with smoother surface finishes. For example, if the first layer 802a has a surface roughness Rₐ of 16 microinches and the second layer 802b has a surface roughness Rₐ of 8 microinches, the two layers may only be in direct contact with one another across approximately 5% of their mating surfaces. The remaining 85% of the mating surface area may represent areas where the layers may be microinches apart and yet do not actually touch one another. Thus, there is no direct thermal conductance between the layers in these non-contacting areas. The only thermally-conductive path between the layers in these non-contacting regions is provided by the gas, which, as discussed above, is at a low enough pressure that it does not significantly contribute to the overall thermal conductance of the thermal isolator.

FIGS. 8E through 8H provide further understanding of this concept. In FIG. 8E, a first material 861 and a second material 862 are shown with an exaggerated surface roughness on facing surfaces. In FIG. 8F, the first material 861 and the second material 862 of FIG. 8E have been brought into contact with one another, although, due to the surface roughness, direct contact only exists in the regions where diagonal hatching is indicated. If the widths of the hatched contact areas across the portions of the first material 861 and the second material 862 are summed, the resulting aggregate region (reproduced at the bottom of the Figure) is approximately 23% of the width of the portions shown.

In FIG. 8G, the first material 861 and the second material 862 are shown again, but with an increased exaggerated surface roughness. In FIG. 8H, the first material 861 and the second material 862 of FIG. 8G have been brought into contact with one another. Again, due to the surface roughness, direct contact only exists in the regions where diagonal hatching is indicated. In this case, direct contact exists over only approximately 8% of the overall width of the portions shown.

While FIGS. 8E through 8H are simplified, two-dimensional examples and do not correlate to any particular roughness values, they serve to demonstrate that increasing surface roughness of mating surfaces results in a decrease in the aggregate direct contact area between the two surfaces, as well an increase in the portions of the mating surfaces that are not actually in direct contact with one another.

Third, the flatness of the interface surface of each layer may be constrained to be within a certain tolerance, e.g., within 0.002″ of absolute flatness. This may help ensure that the little direct contact that exists between layers is evenly distributed across the entire contact area between layers and may prevent localized hotspots that may be caused by a concentrated direct contact area. If the layers are insufficiently flat, this may cause the layers to contact one another in a concentrated area. The heat flow between the layers may be concentrated in the same location, and may experience thermal choking due to the reduced area. This may, in turn, cause the temperature differential to rise in that location and may cause a localized hotspot that may be undesirable from a process uniformity perspective.

Finally, the layers may, by virtue of being clamped between the radical diffuser plate 801 and the precursor delivery plate 803, be held together by a clamping force. For example, the layers 802a and 802b may be held together by approximately 3000 lbs of clamping force for the depicted faceplate assembly 800 (the depicted faceplate assembly 800 has a nominal second layer 802b diameter of approximately 13″). The layer-to-layer contact may typically be “dry,” i.e., no interface material such as an adhesive, braze material, or other filler may be present.

It is to be understood that the faceplate assemblies and other components discussed herein may be provided as part of a semiconductor process chamber, as discussed earlier in this disclosure. In some implementations, one or more such semiconductor process chambers may be provided as process stations in a multi-station semiconductor processing tool. In some implementations, a single process chamber may include multiple processing stations, each with their own faceplate assemblies.

Another feature of the thermal isolator 802 that may assist in reducing heat conduction through the thermal isolator 802 is the presence of an annular thermal break 864. The annular thermal break 864 may take the form of an annular recess in the thermal isolator. The annular recess may be located such that the mid-diameter of the annular recess is located substantially at the mid-diameter or mid-radius of the coolant plenum(s) 850 (or equivalent location of a non-circular/non-arcuate coolant plenum 850). The annular thermal break 864 may act to prevent or restrict heat transfer out of the thermal isolator 802 near the outer perimeter of the thermal isolator 802 and into the coolant plenum 850. This may serve to keep the thermal isolator 802 at a more uniform temperature across the area where the radical through-holes 808 are located.

The various faceplate assemblies shown isometric or other three-dimensional views in the Figures are nominally designed for use in processing 300 mm semiconductor wafers and typically have interior diameters of approximately 13″. However, it is to be understood that similar design concepts may be practiced with faceplate assemblies designed for other sizes of semiconductor wafers, e.g., 450 mm semiconductor wafers, and that such designs may feature larger corresponding dimensions than those shown.

It is also to be understood that the various design concepts shown herein with respect to separate implementations may be combined, if not otherwise incompatible, into other implementations. For example, the multi-layered thermal isolator of FIGS. 8A through 8D may be combined with the concept shown in FIG. 2E to produce a multi-layered thermal isolator where the layers are offset from one another by a plurality of tubular members, thus producing a large gap between the layers.

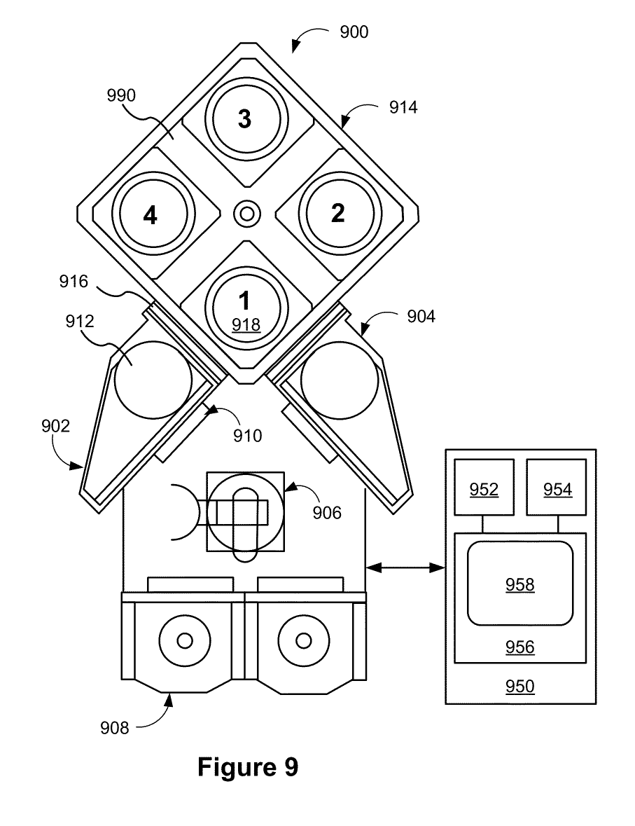

FIG. 9 shows a schematic view of a multi-station processing tool, 900, with an inbound load lock 902 and an outbound load lock 904. A robot 906, at atmospheric pressure, is configured to move wafers from a cassette loaded through a pod 908 into inbound load lock 902 via an atmospheric port 910. A wafer may be placed by the robot 906 on a pedestal 912 in the inbound load lock 902, the atmospheric port 910 may be closed, and the load lock may then be pumped down. If the inbound load lock 902 includes a remote plasma source, the wafer may be exposed to a remote plasma treatment in the load lock prior to being introduced into a processing chamber 914. Further, the wafer also may be heated in the inbound load lock 902, for example, to remove moisture and adsorbed gases. Next, a chamber transport port 916 to processing chamber 914 may be opened, and another robot (not shown) may place the wafer into the processing chamber 914 on a pedestal of a first station shown in the reactor for processing. While the implementation depicted in FIG. 9 includes load locks, it will be appreciated that, in some implementations, direct entry of a wafer into a process station may be provided.

The depicted processing chamber 914 includes four process stations, numbered from 1 to 4 in the implementation shown in FIG. 9. Each station may have a heated or unheated pedestal (shown at 918 for station 1), and gas line inlets. It will be appreciated that in some implementations, each process station may have different or multiple purposes. For example, in some implementations, a process station may be switchable between a conformal film deposition (CFD) and PECVD process mode. Additionally or alternatively, in some implementations, processing chamber 914 may include one or more matched pairs of CFD and PECVD process stations. While the depicted processing chamber 914 comprises four stations, it will be understood that a processing chamber according to the present disclosure may have any suitable number of stations. For example, in some implementations, a processing chamber may have five or more stations, while in other implementations a processing chamber may have three or fewer stations.

Each station may include a separate showerhead assembly that delivers process gases to a wafer at the associated station. In some implementations, some or all of these showerheads may utilize a faceplate assembly as described herein. For example, if a station provides RPD processing, or other processing that may benefit from use of the equipment described herein, to a wafer, the showerhead for that station may include a faceplate assembly as discussed herein. The showerhead may also include other features as discussed herein, such as a circumferential plenum, a plasma dome, and/or a connection to an external remote plasma source.

FIG. 9 also depicts a wafer handling system 990 for transferring wafers within processing chamber 914. In some implementations, wafer handling system 990 may transfer wafers between various process stations and/or between a process station and a load lock. It will be appreciated that any suitable wafer handling system may be employed. Non-limiting examples include wafer carousels and wafer handling robots. FIG. 9 also depicts a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc.

In some implementations, system controller 950 controls all of the activities of process tool 900. System controller 950 executes system control software 958 stored in mass storage device 954, loaded into memory device 956, and executed on processor 952. System control software 958 may include instructions for controlling the timing, mixture of gases, chamber and/or station pressure, chamber and/or station temperature, wafer temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components necessary to carry out various process tool processes. System control software 958 may be coded in any suitable computer readable programming language.

In some implementations, system control software 958 may include input/output control (IOC) sequencing instructions for controlling the various parameters described above. For example, each phase of a CFD process may include one or more instructions for execution by system controller 950. The instructions for setting process conditions for a CFD process phase may be included in a corresponding CFD recipe phase. In some implementations, multiple showerheads, if present, may be controlled independently to allow for separate, parallel process operations to be performed.

Other computer software and/or programs stored on mass storage device 954 and/or memory device 956 associated with system controller 950 may be employed in some implementations. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 918 and to control the spacing between the substrate and other parts of process tool 900.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station or a gas flow into the process station. The pressure control program, or other code, may, for example, control flow of process gas into the precursor delivery plate or the radical source volume.

A heater control program may include code for controlling the current to a heating unit that is used to heat the substrate. Alternatively, the heater control program may control delivery of a heat transfer gas (such as helium) to the substrate. The heater control program may also control, for example, the flow of coolant into the radical diffuser plate, as well as any heaters associated with heating the precursor delivery plate. The heater control program may utilize feedback from temperature sensors within these components to accurately control the temperatures of these components.

A plasma control program may include code for setting RF power levels applied to the process electrodes in one or more process stations. The plasma control program may, in appropriate situations, include code for controlling an external plasma generator and/or valving required to supply process gas to the plasma generator or radical source volume.

In some implementations, there may be a user interface associated with system controller 950. The user interface may include a display screen, graphical software displays of the apparatus and/or process conditions, and user input devices such as pointing devices, keyboards, touch screens, microphones, etc.

In some implementations, parameters adjusted by system controller 950 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 950 from various process tool sensors. The signals for controlling the process may be output on the analog and digital output connections of process tool 900. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

The system controller 950 may provide program instructions for implementing various semiconductor fabrication processes. The program instructions may control a variety of process parameters, such as DC power level, RF bias power level, pressure, temperature, etc. The instructions may control the parameters to operate in-situ deposition of film stacks.

The system controller may typically include one or more memory devices and one or more processors configured to execute the instructions so that the apparatus will perform a method in accordance with the present invention. Machine-readable media containing instructions for controlling process operations in accordance with the present invention may be coupled to the system controller.

While the semiconductor processing tool shown in FIG. 9 depicts a single, four-station process chamber, or module, other implementations of semiconductor processing tools may include multiple modules, each with a single station or multiple stations. Such modules may be interconnected with one another and/or arranged about one or more transfer chambers that may facilitate movement of wafers between the modules. One or more of the stations provided by such multi-module semiconductor processing tools may be equipped with a showerhead including faceplate assemblies and other features as discussed above.

Generally speaking, a showerhead with a faceplate assembly as described herein may be mounted in a reaction chamber above a wafer support configured to support one or more semiconductor wafers. The showerhead may, for example, also serve as a lid, or part of a lid, for the reaction chamber. In other implementations, the showerhead may be a “chandelier” type showerhead and be suspended from the lid of the reaction chamber by a stem or other support structure.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., wafer, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Another aspect of the invention is an apparatus configured to accomplish the methods described herein. A suitable apparatus includes hardware for accomplishing the process operations and a system controller having instructions for controlling process operations in accordance with the present invention. The system controller may be configured, for example, to control gas flows of the first process gas, the second process gas, and the precursor gas into the remote plasma source. The system controller may also control the RF output of the RF coils, and may control the flow rate and temperature of coolant circulated through any cooling channels in the system based on temperatures measured in the faceplate assembly using the temperature probes. The system controller will typically include one or more memory devices and one or more processors configured to execute the instructions so that the apparatus will perform a method in accordance with the present invention. Machine-readable media containing instructions for controlling process operations in accordance with the present invention may be communicatively coupled to the system controller.

Any of the above implementations may be used alone or together with one another in any combination. Although various implementations may have been motivated by various deficiencies with the prior art, which may be discussed or alluded to in one or more places in the specification, the implementations do not necessarily address any of these deficiencies. In other words, different implementations may address different deficiencies that may be discussed in the specification. Some implementations may only partially address some deficiencies or just one deficiency that may be discussed in the specification, and some implementations may not address any of these deficiencies.

While various implementations have been described herein, it should be understood that they have been presented by way of example only, and not limitation. Thus, the breadth and scope of the present disclosure should not be limited by any of the implementations described herein, but should be defined only in accordance with the following and later-submitted claims and their equivalents.

It will be understood that unless features in any of the above-described implementations are expressly identified as incompatible with one another or the surrounding context implies that they are mutually exclusive and not readily combinable in a complementary and/or supportive sense, the totality of this disclosure contemplates and envisions that specific features of those implementations can be selectively combined to provide one or more comprehensive, but slightly different, technical solutions. It will therefore be further appreciated that the above description has been given by way of example only and that modifications in detail may be made within the scope of the disclosure.

1. A showerhead for semiconductor processing operations comprising:
a precursor delivery plate with a first side and an opposing second side;
a radical diffuser plate with a first side and an opposing second side, wherein the second side of the radical diffuser plate faces the first side of the precursor delivery plate;
a thermal isolator interposed between the precursor delivery plate and the radical diffuser plate; and
a pattern of radical through-holes, wherein each of the radical through-holes:
passes through the precursor delivery plate, the radical diffuser plate, and the thermal isolator,
has a hole center axis that is substantially normal to the precursor delivery plate, the radical diffuser plate, and the thermal isolator, and
maintains a substantially uniform cross-sectional area perpendicular to the hole center axis of the radical through-hole through the precursor delivery plate, the radical diffuser plate, and the thermal isolator.

2. The showerhead of claim 1, wherein the thermal isolator is configured to control heat flow between the radical diffuser plate and the precursor delivery plate to be less than the heat flow between the radical diffuser plate and the precursor delivery plate would be were the radical diffuser plate and the precursor delivery plate to be in direct thermal contact and thickened such that the first side of the radical diffuser plate and the second side of the precursor delivery plate remain at the same distance.

3. The showerhead of claim 1, wherein:
the precursor delivery plate includes a pattern of gas delivery holes and one or more internal gas distribution passages,
each of the gas delivery holes has a hole center axis that is substantially normal to the precursor delivery plate, the radical diffuser plate, and the thermal isolator,
each of the gas delivery holes is fluidly connected to at least one of the one or more gas distribution passages, and
each of the gas delivery holes exits the precursor delivery plate on the second side of the precursor delivery plate.

4. The showerhead of claim 1, wherein the radical through-holes have a length-to-diameter ratio of between 7:1 and 10:1.

5. The showerhead of claim 1, wherein the radical through-holes have a length-to-diameter ratio of between 6:1 and 11:1.

6. The showerhead of claim 1, wherein the radical through-holes have a length of at least 0.25″.

7. The showerhead of claim 1, wherein the radical diffuser plate includes one or more first internal cooling passages extending across the radical diffuser plate, wherein the one or more first internal cooling passages are fluidly isolated from the radical through-holes within the radical diffuser plate.

8. The showerhead of claim 7, wherein:
the first internal cooling passages include an array of passages, wherein:
each passage follows a path that is, on average, substantially parallel to a reference plane that is substantially perpendicular to the first side of the radical diffuser plate, and
each passage has a first end fluidly connected with an inlet and a second end fluidly connected with an outlet.

9. The showerhead of claim 7, wherein:
the first internal cooling passages include an array of passages, wherein:
each passage follows a path that is, on average, substantially parallel to a reference plane that is substantially perpendicular to the first side of the radical diffuser plate, and
each passage that is located on a first side of the reference plane has a first end fluidly connected with a first inlet and a second end fluidly connected with a first outlet, and
each passage that is located on a second side of the reference plane opposite the first side of the reference plane has a first end fluidly connected with a second inlet and a second end fluidly connected with a second outlet.

10. The showerhead of claim 9, wherein:
the first inlet, the second inlet, and first outlet, and the second outlet are each connected with their respective passages via separate coolant plenums that are substantially arcuate in shape and that are radially arranged about a center axis of the radical diffuser plate.

11. The showerhead of claim 7, wherein:
the first internal cooling passages include an array of first passages;
each of the first passages follow a first path that is, on average, substantially parallel to a reference plane that is substantially perpendicular to the first side of the radical diffuser plate;
the first internal cooling passages include an array of second passages;
each of the second passages follows a second path that is, on average, substantially parallel to the reference plane;
the first passages and the second passages are fluidly isolated from one another within the radical diffuser plate;
each first passage has a first end that is fluidly connected with a first inlet and a second end opposite the first end of the first passage that is fluidly connected with a first outlet;
each second passage has a first end that is fluidly connected with a second inlet and a second end opposite the first end of the second passage that is fluidly connected with a second outlet; and
the first inlet, the second inlet, the first outlet, and the second outlet are configured such that:
cooling fluid flowed into the first inlet flows through the first passages and out of the first outlet in a first average direction,
cooling fluid flowed into the second inlet flows through the second passages and out of the second outlet in a second average direction, and
the first average direction and the second average direction are substantially opposing directions.

12. The showerhead of claim 1, further comprising:
a circumferential plenum, wherein the circumferential plenum:
has an interior perimeter,
is proximate to the first side of the radical diffuser plate, and
is configured to flow gas in a substantially evenly-distributed manner across the interior perimeter and substantially towards a center axis of the radical diffuser plate.

13. The showerhead of claim 12, further comprising:
a plasma dome, the plasma dome having an interior surface that is substantially axially symmetric about the center axis of the radical diffuser plate, one or more radical gas inlets located on one end of the plasma dome near the center axis of the radical diffuser plate, and a mounting interface located on an opposing end of the plasma dome and configured to connect the plasma dome with the showerhead such that the interior surface of the plasma dome and the first side of the radical diffuser plate define a radical source volume and such that gas flow from the circumferential plenum flows into the radical source volume.

14. The showerhead of claim 13, wherein the circumferential plenum is located in an adapter interposed between the plasma dome and the radical diffuser plate.

15. The showerhead of claim 13, wherein the circumferential plenum is located in the plasma dome near the mounting interface.

16. The showerhead of claim 1, wherein:
the thermal isolator comprises a plate with a thermal conductivity substantially lower than respective thermal conductivities of the precursor delivery plate and the radical diffuser plate.

17. The showerhead of claim 1, wherein the thermal isolator comprises:
a gap between the radical diffuser plate and the precursor delivery plate, wherein the gap defines a free volume between the radical diffuser plate and the precursor delivery plate; and
a number of tubular structures corresponding to the number of radical through-holes in the pattern of radical through-holes, wherein each tubular structure:
corresponds with a different one of the radical through-holes,
has an internal diameter substantially equal to a nominal diameter of the corresponding radical through-hole,
spans the gap, and
substantially isolates the radical through-hole from the free volume with respect to fluidic communication.

18. The showerhead of claim 17, wherein at least one of the tubular structures is a discrete tube segment.

19. The showerhead of claim 18, wherein the at least one of the tubular structures is made from a material selected from the group consisting of quartz or sapphire.

20. The showerhead of claim 1, wherein the thermal isolator comprises:
at least two stacked layers, each layer including the radical through holes.

21. The showerhead of claim 20, wherein:
the thermal isolator further comprises a first interface between a first mating surface of one of the layers and a second mating surface of a neighboring layer,
at least one of the first mating surface and the second mating surface has a surface roughness Rₐ value of about 8 to 16 microinches or higher.

22. The showerhead of claim 20, wherein:
the layers have an absolute flatness of about 0.002″ across each layer.

23. The showerhead of claim 3, wherein the radical through-holes exit the second side of the precursor delivery plate via openings on a first plane and the gas delivery holes exit the second side of the precursor delivery plate via openings on a second plane offset from the first plane by a first, non-zero distance in a direction away from the first side of the precursor delivery plate.

24. The showerhead of claim 23, wherein the first, non-zero distance is greater than 0.25″.

25. The showerhead of claim 23, wherein the first, non-zero distance is between 0.25″ and 3″.

26. The showerhead of claim 23, wherein the first, non-zero distance is between 3″ and 12″.

27. The showerhead of claim 3, wherein the radical through-holes exit the second side of the precursor delivery plate via openings on a first plane and the gas delivery holes exit the second side of the precursor delivery plate via openings on a second plane offset from the first plane in a direction away from the first side of the precursor delivery plate and far enough that radicalized gas flowed from the radical diffuser plate via the openings on the first plane exhibits substantially fully-developed flow before encountering the second plane.

28. The showerhead of claim 1, wherein the radical diffuser plate is at least partially coated with a material that inhibits radical recombination with the radical diffuser plate.

29. The showerhead of claim 28, wherein the material is selected from the group consisting of aluminum nitride, quartz, and sapphire.

30. The showerhead of claim 1, wherein the showerhead further includes a process chamber, and the radical diffuser plate, the thermal isolator, and the precursor delivery plate are configured to deliver process gases to the process chamber.

31. The showerhead of claim 30, wherein the showerhead further includes one or more additional process chambers, and the process chamber and the one or more additional process chambers form a multi-chamber semiconductor processing tool.

32. The showerhead of claim 30, further comprising a second radical diffuser plate, a second thermal isolator, and a second precursor delivery plate, wherein:
the second radical diffuser plate, the second thermal isolator, and the second precursor delivery plate are arranged in a manner similar to the radical diffuser plate, the thermal isolator, and the precursor delivery plate,
the process chamber includes at least a first processing station and a second processing station,
the radical diffuser plate, the thermal isolator, and the precursor delivery plate are configured to deliver process gas to the first processing station, and
the second radical diffuser plate, the second thermal isolator, and the second precursor delivery plate are configured to deliver process gas to the second processing station.

33. A method for using a showerhead for semiconductor processing operations, the showerhead including:
a precursor delivery plate with a first side and an opposing second side;
a radical diffuser plate with a first side and an opposing second side, wherein the second side of the radical diffuser plate faces the first side of the precursor delivery plate;
a thermal isolator interposed between the precursor delivery plate and the radical diffuser plate; and
a pattern of radical through-holes, wherein:
each of the radical through-holes passes through the precursor delivery plate, the radical diffuser plate, and the thermal isolator,
each of the radical through-holes has a hole center axis that is substantially normal to the precursor delivery plate, the radical diffuser plate, and the thermal isolator, and
each of the radical through-holes maintains a substantially uniform cross-sectional area perpendicular to the hole center axis of the radical through-hole through the precursor delivery plate, the radical diffuser plate, and the thermal isolator,
the precursor delivery plate includes a pattern of gas delivery holes and one or more internal gas distribution passages,
each of the gas delivery holes has a hole center axis that is substantially normal to the precursor delivery plate, the radical diffuser plate, and the thermal isolator,
each of the gas delivery holes is fluidly connected to at least one of the one or more gas distribution passages, and
each of the gas delivery holes exits the precursor delivery plate on the second side of the precursor delivery plate; and
the method comprising:
maintaining the precursor delivery plate at a first temperature;
maintaining the radical diffuser plate at a second temperature;
providing a first process gas via the gas delivery holes while the diffuser delivery plate is at the first temperature; and
providing a second process gas via the radical through-holes while the radical diffuser plate is at the second temperature.

34. A reactor for semiconductor processing operations comprising:
a reaction chamber;
a wafer support located within the reaction chamber; and
a showerhead including:
a precursor delivery plate with a first side and an opposing second side;
a radical diffuser plate with a first side and an opposing second side, wherein the second side of the radical diffuser plate faces the first side of the precursor delivery plate;
a thermal isolator interposed between the precursor delivery plate and the radical diffuser plate; and
a pattern of radical through-holes, wherein:
each of the radical through-holes passes through the precursor delivery plate, the radical diffuser plate, and the thermal isolator,
each of the radical through-holes has a hole center axis that is substantially normal to the precursor delivery plate, the radical diffuser plate, and the thermal isolator,
each of the radical through-holes maintains a substantially uniform cross-sectional area perpendicular to the hole center axis of the radical through-hole through the precursor delivery plate, the radical diffuser plate, and the thermal isolator,
the showerhead and the wafer support are configured such that the wafer support is beneath the showerhead within the reaction chamber.

35. A thermal isolator comprising:
a first side;
a second side substantially parallel to, and offset from, the first side;
a plurality of tubular structures spanning between the first side and the second side, the tubular structures arranged in a distributed pattern across the first side and the second side, wherein:
the tubular structures substantially prevent fluid flow between volumes within the tubular structures and a volume substantially defined between the first side and the second side.

36. The thermal isolator of claim 35, further comprising a perimeter wall spanning between the first side and the second side and encircling the plurality of tubular structures, wherein the perimeter wall, the first side, the second side, and outermost surfaces of the tubular structures define a hollow internal volume of the thermal isolator.

37. The thermal isolator of claim 36, further comprising one or more ports in fluid communication with the hollow internal volume of the thermal isolator.
